(19) United States
(12) Patent Application Publication
(10) Pub. No.: US 2021/0028239 A1
(43) Pub. Date: Jan. 28, 2021

(54) LIGHT-EMITTING DEVICE, AND ELECTRONIC APPARATUS

(71) Applicant: SEIKO EPSON CORPORATION, Tokyo (JP)

(72) Inventors: Jun IROBE, Chino-shi (JP); Takeshi KOSHIHARA, Matsumoto-shi (JP)

(73) Assignee: SEIKO EPSON CORPORATION, Tokyo (JP)

(21) Appl. No.: 16/936,775

(22) Filed: Jul. 23, 2020

(30) Foreign Application Priority Data
Jul. 24, 2019 (JP) 2019-135921

(51) Int. Cl. H01L 27/32

(52) U.S. Cl. CPC H01L 27/322; H01L 27/3218

(57) ABSTRACT

A light-emitting device includes a semi-transmissive reflection layer, a first reflection layer that is disposed in a first sub-pixel, a second reflection layer that is disposed in a second sub-pixel, the second sub-pixel that emits same color light as the first sub-pixel, and a light-emitting functional layer that is disposed between the first reflection layer and the semi-transmissive reflection layer and the semi-transmissive reflection layer. A distance between the second reflection layer and the semi-transmissive reflection layer is longer than a distance between the first reflection layer and the semi-transmissive reflection layer.

The present application is based on, and claims priority from JP Application Serial Number 2019-135921, filed Jul. 24, 2019, the disclosure of which is hereby incorporated by reference herein in its entirety.

### BACKGROUND

### 1. Technical Field

The present disclosure relates to a light-emitting device, a method for manufacturing the light-emitting device, and an electronic apparatus including the light-emitting device.

### 2. Related Art

Known display devices include an organic electroluminescent (EL) element and a color filter for transmitting light in a predetermined wavelength range. For example, the display device in JP-A-2017-146372 includes an organic EL element, a reflective layer, and a common electrode that functions as a semi-transmissive reflective layer, and has a resonance structure configured to resonate light emitted from the organic EL element. Specifically, the optical path length between the reflective layer and the common electrode is optimized for each color light of R, G and B to increase intensity of the light in wavelengths of each color through interference and improve light extraction efficiency. Note that the resonance structure is set in common across display surfaces for each color light.

In JP-A-2017-146372, the display device is used as a head mounted display (HMD). The HMD includes an optical system with a projector lens and a user is shown a virtual image by enlarging an image on the display device. HMDs of this type are required to be downsized to increase comfort for the user. Thus, display devices are being made smaller and in higher definition. However, in order to achieve a large virtual image on a small display device, the angle of view needs to be increased.

In a typical display device such as that disclosed in JP-A-2017-146372, extraction efficiency may decrease and chromaticity may shift as the principal ray tilts (see FIG. 15 of JP-A-2017-146372). When the principal ray tilts, the optical path length and the phase condition for reflection change, and this causes the resonance wavelength to shift and chromaticity to change. When the angle of view in the display device is increased, a change in chromaticity is noticeable at peripheral edge portions of the display area of the display device. Thus, typical display devices have insufficient visual field angle characteristics, which is a problem.

### SUMMARY

A light-emitting device according to the present application is a light-emitting device including a first sub-pixel and a second sub-pixel in a display region, the light-emitting device including a reflective layer, a semi-transmissive reflective layer, and a light-emitting functional layer provided between the reflective layer and the semi-transmissive reflective layer, the light-emitting device further having a resonance structure in which light radiated from the light-emitting functional layer resonates between the reflective layer and the semi-transmissive reflective layer, wherein a wavelength range of light, emitted by the first sub-pixel and the second sub-pixel, from the resonance structure is a first wavelength range, and a distance between the reflective layer and the semi-transmissive reflective layer in the second sub-pixel is greater than a distance between the reflective layer and the semi-transmissive reflective layer in the first sub-pixel.

Further, the light-emitting device is a light-emitting device including a first sub-pixel and a second sub-pixel in a display region, the light-emitting device including a reflective layer, a semi-transmissive reflective layer, and a light-emitting functional layer provided between the reflective layer and the semi-transmissive reflective layer, and the light-emitting device further having a resonance structure in which light radiated from the light-emitting functional layer resonates between the reflective layer and the semi-transmissive reflective layer, wherein a wavelength range of light, emitted by the first sub-pixel and the second sub-pixel, from the resonance structure is a first wavelength range, and a wavelength range of light emitted at a predetermined tilt angle from the second sub-pixel matches a wavelength range of light emitted in a vertical direction from the first sub-pixel.

The light-emitting device preferably further includes a pixel electrode provided between the reflective layer and the light-emitting functional layer, and an insulating layer provided between the reflective layer and the pixel electrode, wherein the insulating layer preferably includes a first layer formed of a first material, and a second layer formed of a second material, which is different from the first material, and the second layer in the second sub-pixel is preferably thicker than the second layer in the first sub-pixel.

The first sub-pixel is preferably disposed in a reference area serving as a reference in the display region, and the second sub-pixel is preferably disposed in an area, which is different from the reference area.

An electronic apparatus preferably includes the above-described light-emitting device.

A method for manufacturing a light-emitting device according to the present application is a method for manufacturing a light-emitting device including a reflective layer, an insulating layer, a light-emitting functional layer, a semi-transmissive reflective layer, and moreover having a resonance structure in which light radiated from the light-emitting functional layer resonates between the reflective layer and the semi-transmissive reflective layer, the method including forming a first layer of the insulating layer formed of a first material, forming a first material layer on the first layer using a second material, which is different from the first material, forming a resist mask on the first material layer and patterning the first material layer, with the first layer serving as an etch stopper, thereby forming a second layer of the insulating layer, forming a second material layer on the second layer using the second material, and forming a resist mask on the second material layer and patterning the second material layer, thereby thickening the second layer of the insulating layer, wherein the second layer in a second sub-pixel disposed in an area different from a reference area serving as a reference in a display region is thicker than the second layer in a first sub-pixel disposed in the reference area.

Further, a method for manufacturing a light-emitting device is a method for manufacturing a light-emitting device including a reflective layer, an insulating layer, a light-emitting functional layer, a semi-transmissive reflective layer, and moreover having a resonance structure in which light radiated by the light-emitting functional layer resonates between the reflective layer and the semi-transmissive reflective layer, the method including forming a first layer of the insulating layer, forming a material layer on the first layer using a second material, which is different from a first material, forming a resist on the material layer and performing gradient exposure using a gradient exposure mask, and patterning the material layer using a resist mask formed through the gradient exposure to transfer a shape of the resist mask onto the material layer, thereby forming a second layer of the insulating layer, wherein the second layer in a second sub-pixel disposed in an area different from a reference area serving as a reference in a display region is thicker than the second layer in a first sub-pixel disposed in the reference area.

### BRIEF DESCRIPTION OF THE DRAWINGS

FIG. 1 is a schematic plan view illustrating a configuration of an organic EL device according to a first embodiment.

FIG. 2 is an equivalent circuit diagram illustrating an electrical configuration of a light-emitting pixel in the organic EL device.

FIG. 3 is a schematic plan view illustrating a configuration of a light-emitting pixel.

FIG. 4 is a schematic cross-sectional view of a light-emitting pixel taken along the X direction.

FIG. 5A is a schematic cross-sectional view illustrating an optical resonance structure in a light-emitting pixel.

FIG. 5B is a table of examples of thicknesses of an adjustment layer and associated layers.

FIG. 6A is a schematic diagram illustrating an optical system of an apparatus that displays a virtual image.

FIG. 6B is a schematic cross-sectional view of a sub-pixel.

FIG. 7 is a graph showing correlation between a principal ray angle and adjustment layer thickness.

FIG. 8A is a diagram illustrating the number of adjustment layers in sub-pixels for different colors in a reference area.

FIG. 8B is a diagram illustrating the number of adjustment layers in sub-pixels for different colors in a peripheral area.

FIG. 9 is a process flow chart illustrating a flow of manufacturing an adjustment layer.

FIG. 10A is a cross-sectional view illustrating a manufacturing process in one step.

FIG. 10B is a cross-sectional view illustrating a manufacturing process in one step.

FIG. 10C is a cross-sectional view illustrating a manufacturing process in one step.

FIG. 10D is a cross-sectional view illustrating a manufacturing process in one step.

FIG. 10E is a cross-sectional view illustrating a manufacturing process in one step.

FIG. 11 is a graph showing distribution of intensity of wavelength components for each area.

FIG. 12 is an XY chromaticity diagram showing chromaticity of a representative sub-pixel for each area.

FIG. 13A is a diagram illustrating divided display areas.

FIG. 13B is a diagram illustrating divided display areas.

FIG. 13C is a diagram illustrating divided display areas.

FIG. 13D is a diagram illustrating divided display areas.

FIG. 14 is a process flow chart illustrating a flow of manufacturing an adjustment layer.

FIG. 15A is a cross-sectional view illustrating a manufacturing process in one step.

FIG. 15B is a cross-sectional view illustrating a manufacturing process in one step.

FIG. 15C is a cross-sectional view illustrating a manufacturing process in one step.

FIG. 16 is a perspective view illustrating a head-mounted display as an electronic apparatus.

### DESCRIPTION OF EXEMPLARY EMBODIMENTS

### 1. First Embodiment

### Overview of Light-Emitting Device

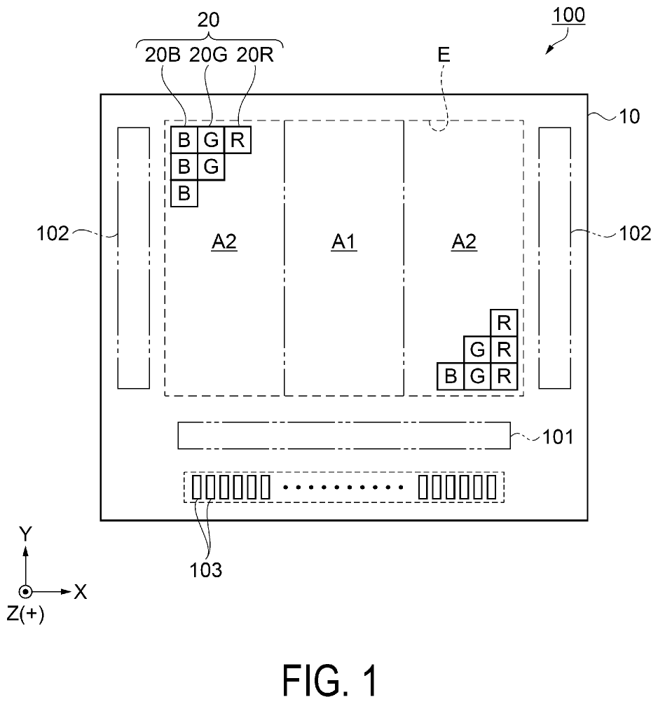

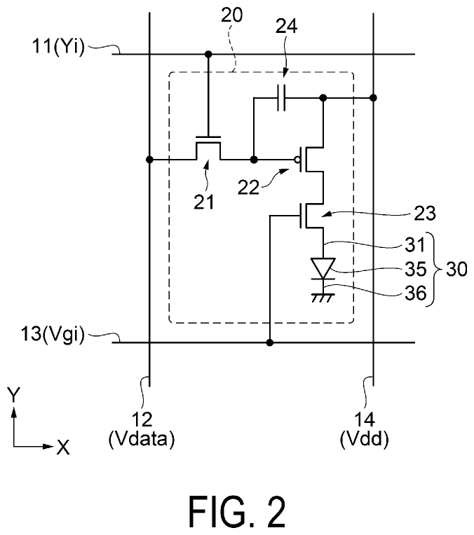

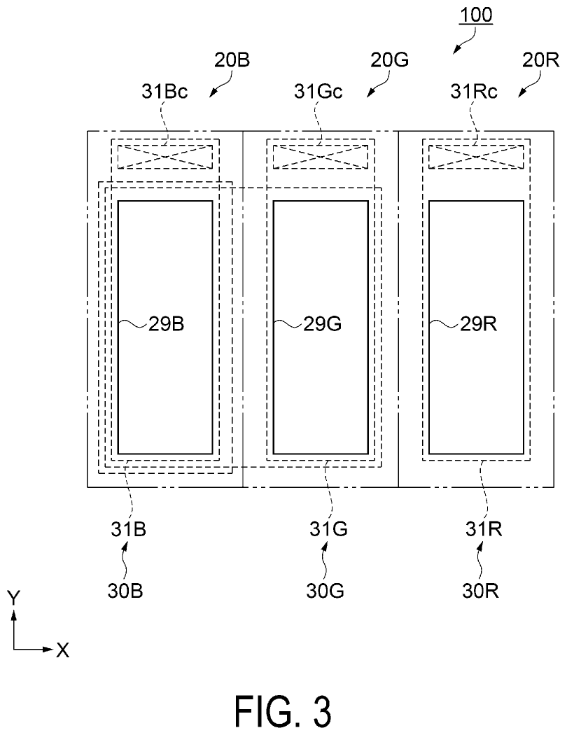

First, an organic EL device as an example of a light-emitting device according to this embodiment will be described with reference to FIGS. 1 to 3. FIG. 1 is a schematic plan view illustrating a configuration of the organic EL device. FIG. 2 is an equivalent circuit diagram illustrating an electrical configuration of a light-emitting pixel in the organic EL device. FIG. 3 is a schematic plan view illustrating a configuration of a light-emitting pixel in the organic EL device.

As illustrated in FIG. 1, an organic EL device 100 as an example of a light-emitting device includes an element substrate 10, a plurality of light-emitting pixels 20 arranged in a matrix in a display region E of the element substrate 10, a data line drive circuit 101 and a scanning line drive circuit 102 as peripheral circuits that drive and control the plurality of light-emitting pixels 20, and a plurality of external connection terminals 103 used to electrically couple the organic EL device 100 to an external circuit. The organic EL device 100 according to the present embodiment is an active driven and top-emitting light-emitting device. Note that the display region E may also be referred to as a display surface E.

A light-emitting pixel 20B that emits blue light (B), a light-emitting pixel 20G that emits green light (G), and a light-emitting pixel 20R that emits red light (R) are disposed in the display region E. In FIG. 1, light-emitting pixels 20 that emit the same color light are arranged in the vertical direction and light-emitting pixels 20 that emit different color light are arranged repeatedly in the order of B, G and R in the lateral direction. Such an arrangement of light-emitting pixels 20 is referred to as a stripe arrangement. The arrangement of the light-emitting pixels 20 is not limited to this arrangement. For example, the arrangement of light-emitting pixels 20 that emit different color light in the lateral direction does not need to be in the order of B, G and R, and may be in the order of R, G and B, for example. In the following description, the vertical direction along which the light-emitting pixels 20 that emit the same color light are arranged is described as a Y direction, and a direction orthogonal to the Y direction is described as an X direction. A view of the element substrate 10 from a light extraction direction of the light-emitting pixels 20 is described as a plan view. Note that three adjacent sub-pixels of B, G and R constitute one pixel in a display unit.

A detailed configuration of the light-emitting pixel 20 is given below. Each of the light-emitting pixels 20B, 20G and 20R according to the present embodiment includes an organic electroluminescent element as a light-emitting element, and a color filter corresponding to each color of B, G, and R. Light emitted from the organic EL element is converted into the colors B, G, and R to enable full color display. Note that the organic electroluminescent element is referred to as an organic EL element. In addition, each light-emitting pixel 20B, 20G and 20R is built with an optical resonance structure that enhances luminance in a specific wavelength within a wavelength range of light emitted from the organic EL element.

In the organic EL device 100, the light-emitting pixels 20B, 20G and 20R function as sub-pixels, and one pixel unit in the image display consists of the three light-emitting pixels 20B, 20G and 20R that emit light corresponding to B, G and R, respectively. Note that the pixel unit is not limited to this configuration and may include a light-emitting pixel 20 that emits light of a color other than B, G and R (including white).

The display region E is divided into two regions. Specifically, the center of the display region E corresponds to an area A1, and either side of the area A1 in the X direction corresponds to an area A2. In other words, the display region E is divided into vertical stripe display areas in the order of the area A2, the area A1, and the area A2 along the X direction. Note that a sub-pixel disposed in the area A1 serving as a reference area corresponds to a first sub-pixel. A sub-pixel disposed in the surrounding area A2, which is different to the area A1, corresponds to a second sub-pixel. The first sub-pixel and the second sub-pixel emit the same color light. The configuration of the sub-pixel differs between the area A1 and the area A2, and this will be described in detail below.

The plurality of external connection terminals 103 are provided along a first side portion of the element substrate 10 and are aligned in the X direction. The data line drive circuit 101 is disposed between the external connection terminals 103 and the display region E in the Y direction and extends in the X direction. Further, a pair of the scanning line drive circuits 102 are provided sandwiching the display region E in the X direction.

As described above, in the display region E, a plurality of the light-emitting pixels 20 are provided in a matrix. As illustrated in FIG. 2, the element substrate 10 is provided with a scanning line 11, a data line 12, a lighting control line 13 and a power source line 14 as signal lines corresponding to the light-emitting pixels 20.

In the present embodiment, the scanning line 11 and the lighting control line 13 extend in parallel with the X direction, and the data line 12 and the power source line 14 extend in parallel with the Y direction.

In the display region E, a plurality of the scanning lines 11 and a plurality of the lighting control lines 13 are provided corresponding to m-rows in the plurality of light-emitting pixels 20 arranged in a matrix. Each scanning line 11 and each lighting control line 13 is coupled to a pair of the scanning line drive circuits 102 illustrated in FIG. 1. A plurality of the data lines 12 and a plurality of the power source lines 14 are provided corresponding to n-columns in the plurality of light-emitting pixels 20 arranged in a matrix. Each of the plurality of data lines 12 is coupled to the data line drive circuit 101 illustrated in FIG. 1, and each of the plurality of power source lines 14 is coupled to any one of the plurality of external connection terminals 103.

The pixel circuit of each light-emitting pixel 20 is made up of a first transistor 21, a second transistor 22, a third transistor 23, a storage capacitor 24, and an organic EL element 30 serving as a light-emitting element, and these components are provided near an intersection between the scanning line 11 and the data line 12. The organic EL element 30 includes a pixel electrode 31 that is an anode, a cathode 36 that is a cathode, and a functional layer 35 that includes a light-emitting layer and is interposed between these two electrodes. The cathode 36 is an electrode provided in common across the plurality of light-emitting pixels 20. A reference potential Vss or a GND potential that is lower than a power supply voltage Vdd applied to the power source line 14 is applied to the cathode 36.

The first transistor 21 and the third transistor 23 are, for example, n-channel transistors. The second transistor 22 is, for example, a p-channel transistor.

The gate electrode of the first transistor 21 is coupled to the scanning line 11, one current terminal of the first transistor 21 is coupled to the data line 12, and the other current terminal of the first transistor 21 is coupled to the gate electrode of the second transistor 22 and one electrode of the storage capacitor 24.

One current terminal of the second transistor 22 is coupled to the power source line 14 and the other electrode of the storage capacitor 24. The other current terminal of the second transistor 22 is coupled to one current terminal of the third transistor 23. In other words, the second transistor 22 and the third transistor 23 share one current terminal of a pair of current terminals.

The gate electrode of the third transistor 23 is coupled to the lighting control line 13 and the other current terminal of the third transistor 23 is coupled to the pixel electrode 31 of the organic EL element 30. In the pairs of current terminals in each of the first transistor 21, the second transistor 22 and the third transistor 23, one current terminal is a source and the other is a drain.

In such a pixel circuit, the n-channel first transistor 21 enters an ON state when the voltage level of a scanning signal Yi supplied from the scanning line drive circuit 102 to the scanning line 11 reaches a Hi level. The data line 12 and the storage capacitor 24 are electrically coupled to each other when the first transistor 21 is in the ON state. Then, when a data signal is supplied from the data line drive circuit 101 to the data line 12, the potential difference between a voltage level Vdata of the data signal and a power supply voltage Vdd applied to the power source line 14 is stored in the storage capacitor 24.

When the voltage level of the scanning signal Yi supplied to the scanning line 11 from the scanning line drive circuit 102 reaches a Low level, the n-channel first transistor 21 enters an OFF state and a gate-source voltage Vgs of the second transistor 22 is held at the voltage obtained when the voltage level Vdata is applied. After the scanning signal Yi reaches the Low level, the voltage level of a lighting control signal Vgi supplied to the lighting control line 13 reaches the Hi level and the third transistor 23 enters the ON state. In this way, current corresponding to the gate-source voltage Vgs of the second transistor 22 flows between the source and the drain of the second transistor 22. Specifically, this current flows along a path from the power source line 14 to the organic EL element 30 via the second transistor 22 and the third transistor 23.

The organic EL element 30 emits light according to the magnitude of current flowing through the organic EL element 30. The current flowing through the organic EL element 30 is determined based on operating points of the second transistor 22 and the organic EL element 30 set by the voltage Vgs between the gate and the source of the second transistor 22. The voltage Vgs between the gate and the source of the second transistor 22 is the voltage held in the storage capacitor 24 due to a potential difference between the voltage level Vdata of the data line 12 and the power supply voltage Vdd when the scanning signal Yi is at the Hi level. The emission brightness of the light-emitting pixel 20 is defined by the length of time that the voltage level Vdata in the data signal and the third transistor 23 are in the ON state. In other words, the value of the voltage level Vdata in the data signal may provide brightness gradation according to image information in the light-emitting pixel 20 and enable full color display.

Note that in the present embodiment, the pixel circuit of the light-emitting pixel 20 is not limited to having the three transistors 21, 22 and 23 and need only be a pixel circuit capable of displaying and driving a light-emitting pixel. For example, the pixel circuit may have a circuit configuration that uses two transistors. The transistors constituting the pixel circuit may be n-channel transistors, p-channel transistors, or may include both an n-channel transistor and a p-channel type transistor. In other words, the transistors constituting the pixel circuit of the light-emitting pixel 20 may be MOS transistors having an active layer in the semiconductor substrate, thin-film transistors, or field-effect transistors.

As illustrated in FIG. 3, each of the light-emitting pixels 20B, 20G and 20R is rectangular in plan view and is disposed such that the longitudinal direction thereof is aligned with the Y direction. Each of the light-emitting pixels 20B, 20G and 20R is provided with the organic EL element 30 having the equivalent circuit illustrated in FIG. 2. To distinguish between the organic EL elements 30 provided in the light-emitting pixels 20B, 20G and 20R, the organic EL elements 30 may be referred to as an organic EL element 30B, an organic EL element 30G, and an organic EL element 30R, respectively. In order to distinguish between the pixel electrodes 31 in the organic EL elements 30 for each of the light-emitting pixels 20B, 20G, and 20R, the pixel electrodes 31 may be referred to as a pixel electrode 31B, a pixel electrode 31G and a pixel electrode 31R, respectively.

The light-emitting pixel 20B is provided with the pixel electrode 31B and a contact portion 31Bc that electrically couples the pixel electrode 31B and the third transistor 23. Similarly, the light-emitting pixel 20G is provided with the pixel electrode 31G and a contact portion 31Gc that electrically couples the pixel electrode 31G and the third transistor 23. The light-emitting pixel 20R is provided with the pixel electrode 31R and a contact portion 31Rc that electrically couples the pixel electrode 31R and the third transistor 23. The pixel electrodes 31B, 31G and 31R are substantially rectangular in plan view. Each of the contact portions 31Bc, 31Gc and 31Rc is disposed on an upper side of each pixel electrode 31B, 31G and 31R in the longitudinal direction, respectively.

Each of the light-emitting pixels 20B, 20G and 20R has an insulated structure in which adjacent pixel electrodes 31 are electrically insulated from each other and openings 29B, 29G and 29R that define regions in contact with a functional layer are formed on the pixel electrodes 31B, 31G and 31R, respectively. Note that in the present embodiment, the openings 29B, 29G and 29R have the same shape and size.

Structure of Pixel

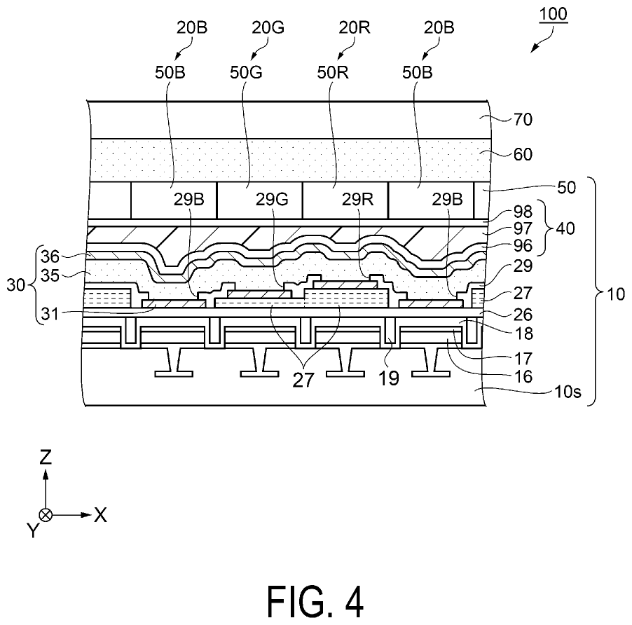

FIG. 4 is a schematic cross-sectional view of a light-emitting pixel taken along the X direction.

Next, the configuration of the light-emitting pixel 20 will be described with reference to FIG. 4. Note that the pixel circuit, which includes the transistors and other components, illustrated in FIG. 3 is not shown in FIG. 4.

As illustrated in FIG. 4, the organic EL device 100 includes the element substrate 10 formed with the light-emitting pixels 20B, 20G 20R, a color filter 50 and other components, and a transparent sealing substrate 70. The element substrate 10 and the sealing substrate 70 are bonded together by a resin layer 60 having both adhesive and transparent properties.

The color filter 50 includes filter layers 50B, 50G and 50R corresponding to the colors B, G and R, respectively. The filter layers 50B, 50G and 50R are disposed on the element substrate 10 corresponding to the light-emitting pixels 20B, 20G and 20R, respectively.

The organic EL device 100 has a top-emitting structure in which emitted light is extracted from the sealing substrate 70 side, and light emitted from the functional layer 35 passes through any one of the corresponding filter layers 50B, 50G and 50R and exits from the sealing substrate 70 side.

In the present embodiment, a silicon substrate is used as a base material 10s of the element substrate 10. Note that, an opaque ceramic substrate or semiconductor substrate may be used because a top-emitting structure is employed.

A pixel circuit layer including the above-described transistors and connection wiring such as contact portions, a reflective electrode 16, a reflectance-enhancing layer 17, a first protective layer 18, an embedded insulating layer 19, a second protective layer 26, an adjustment layer 27, the organic EL element 30, a pixel separation layer 29, an sealing layer 40, the color filter 50, and other components are formed on the base material 10s. Note that this pixel circuit layer is not shown in FIG. 4.

The reflective electrode 16 also functions as a reflective layer in the resonance structure and is formed of a material having light reflectivity and conductivity. For example, metals such as aluminum (Al) and silver (Ag), and alloys of these metals, can be used. In this embodiment, a Ti/Al—Cu alloy is used, and an Al—Cu alloy is used as a reflective surface that reflects light. The reflective electrode 16 is flat and is formed wider than each of the openings 29B, 29G and 29R in each pixel.

The reflectance-enhancing layer 17 is a silicon oxide layer formed on the reflective electrode 16 and functions as a reflectance-enhancing layer that improves light reflectance. The reflectance-enhancing layer 17 is used as a hard mask for patterning in a step for forming the reflective electrode 16. In this step, when the reflective electrode 16 is divided into pixels, grooves are formed around the periphery of the pixels. In other words, as illustrated in FIG. 4, a groove is provided between the reflective electrode 16 of a certain light-emitting pixel 20 and the reflective electrode 16 of a light-emitting pixel 20 adjacent to that light-emitting pixel 20.

The first protective layer 18 is a silicon nitride layer formed on the reflectance-enhancing layer 17 and is formed on the inner surface of the grooves that divide the pixels. For example, a plasma CVD method is used to form the reflectance-enhancing layer 17.

The embedded insulating layer 19 is a silicon oxide layer used to fill and flatten the grooves that divide the pixels. For example, a high density plasma CVD method is used to form the embedded insulating layer 19. The silicon oxide layer is formed on the reflectance-enhancing layer 17 to fill the grooves that divide the pixels. Then, a resist is selectively formed on top portions of the grooves and the entire surface is etched. At this time, the first protective layer 18 is exposed through using the first protective layer 18 as an etch stopper, and the grooves are filled with the embedded insulating layer 19 and flattened.

The second protective layer 26 is a flat silicon nitride layer formed on the first protective layer 18 and the embedded insulating layer 19. The second protective layer 26 corresponds to a first layer of the insulating layer and silicon nitride corresponds to a first material. For example, a plasma CVD method is used to form the second protective layer 26.

The adjustment layer 27 is an adjustment layer for optical path length and is used to adjust the length of the optical path in the resonance structure. The adjustment layer 27 corresponds to a second layer of the insulating layer and is composed of silicon oxide as a second material different to the first material. The adjustment layer 27 has a different number of stacked layers in each area of the display region E. FIG. 4 illustrates the reference area A1. Specifically, in the light-emitting pixel 20G, two adjustment layers 27 are formed on the second protective layer 26. In the light-emitting pixel 20R, four adjustment layers 27 are formed on the second protective layer 26. In the light-emitting pixel 20B, no adjustment layer is formed on the second protective layer 26 and the pixel electrode 31B is formed directly on the second protective layer 26. Note that details of the adjustment layer 27 will be described later.

The pixel separation layer 29 is formed between adjacent pixel electrodes 31 and partitions the openings 29B, 29G and 29R of the pixels. Silicon oxide is used for the pixel separation layer 29.

The organic EL element 30 is configured to sandwich the functional layer 35 between the pixel electrode 31 and the cathode 36.

The pixel electrode 31 is a transparent anode and is formed of a transparent conductive film having light transmittance and conductivity. As a suitable example, Indium tin oxide (ITO) is used. After forming the film using, for example, sputtering, the pixel electrode 31 is partitioned into sub-pixels through patterning. Note that the functional layer 35 will be described later.

The cathode 36 is a cathode that also functions as a semi-transmissive reflective layer in the resonance structure and, in the present embodiment, a Mg—Ag alloy semi-transmissive reflective thin film in which Mg and Ag are co-deposited is used.

The sealing layer 40 includes a first inorganic sealing layer 96, an organic intermediate layer 97, and a second inorganic sealing layer 98.

The first inorganic sealing layer 96 is made of a material having excellent gas barrier properties and transparency and is formed to cover the cathode 36. For example, an inorganic compound such as a metal oxide, for example, silicon oxide, silicon nitride, silicon oxynitride, and titanium oxide is used to form the first inorganic sealing layer 96. As a suitable example, silicon oxynitride is used for the first inorganic sealing layer 96.

The organic intermediate layer 97 is a transparent organic resin layer formed over the first inorganic sealing layer 96. As a suitable example, epoxy resin is used as the material of the organic intermediate layer 97. The material is applied by a printing method or a spin coating method and cured to cover and flatten foreign material and projections and depressions on the surface of the first inorganic sealing layer 96.

The second inorganic sealing layer 98 is an inorganic compound layer formed over the organic intermediate layer 97. Similar to the first inorganic sealing layer 96, the second inorganic sealing layer 98 has both transparency and gas barrier properties and is formed using an inorganic compound having excellent water resistance and heat resistance. As a suitable example, silicon oxynitride is used for the second inorganic sealing layer 98.

The color filter 50 is formed on the second inorganic sealing layer 98 having a flattened surface. Each of the filter layers 50B, 50G and 50R of the color filter 50 is formed by applying, exposing and developing a photosensitive resin containing a pigment corresponding to each color.

Optical Resonance Structure

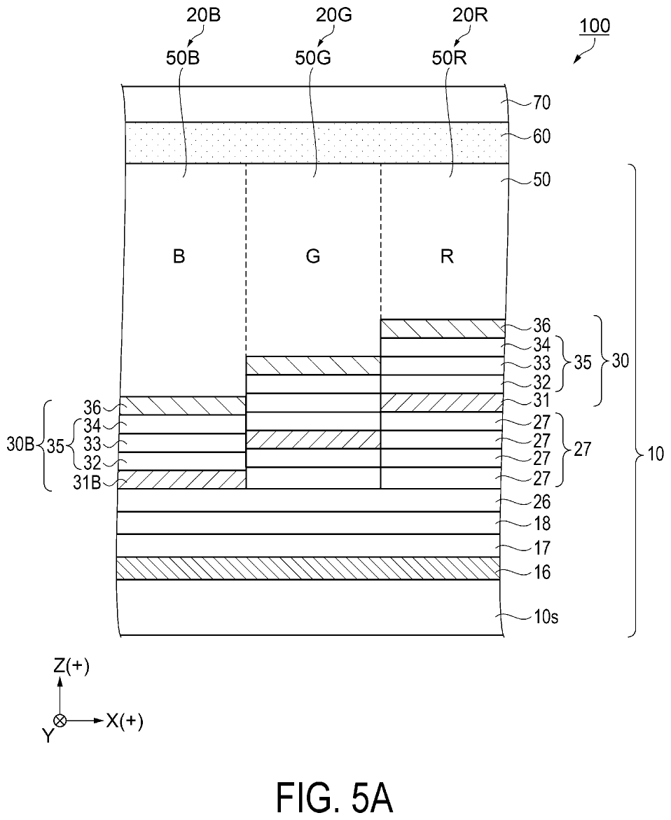

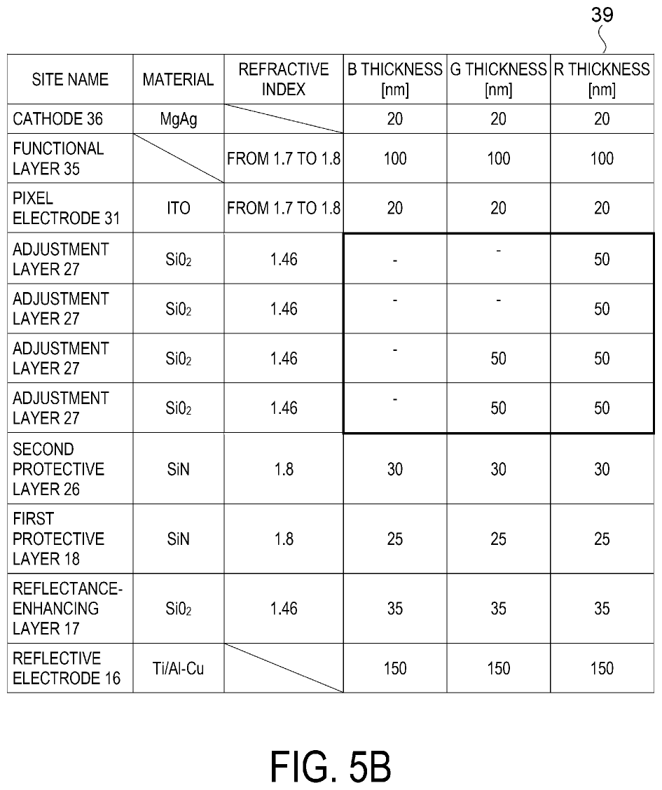

FIG. 5A is a schematic cross-sectional view illustrating an optical resonance structure in the light-emitting pixel and corresponds to FIG. 4. Next, the optical resonance structure in the organic EL device 100 and the configuration of the organic EL element 30 will be described with reference to FIG. 5A.

As described above, the organic EL element 30 has a configuration in which the functional layer 35 is sandwiched between the pixel electrode 31 and the cathode 36.

The functional layer 35 is an organic light-emitting layer including a hole injecting layer (HIL) 32, an organic light-emitting layer (EML) 33 and an electron transport layer (ETL) 34, which are stacked in the stated order from the pixel electrode 31 side. Each of these layers is formed using, for example, a vapor deposition method.

Applying drive potential between the pixel electrode 31 and the cathode 36 causes holes to be injected into the functional layer 35 from the pixel electrode 31 and electrons to be injected into the functional layer 35 from the cathode 36. In the organic light-emitting layer 33 included in the functional layer 35, excitons are formed by the injected holes and electrons. When the excitons decay, some of the resulting energy is radiated as fluorescence or phosphorescence. Note that, in addition to the hole injecting layer 32, the organic light-emitting layer 33 and the electron transport layer 34, the functional layer 35 may include a hole transport layer, an electron injecting layer, or an intermediate layer that improves or controls injectability and transport of the holes or electrons injected into the organic light-emitting layer 33.

When drive voltage is applied to the organic EL element 30, the organic light-emitting layer 33 radiates white light. White light can be also obtained by combining organic light-emitting layers that emit blue (B) light, green (G) light and red (R) light, respectively. Further, a pseudo-white light can be obtained by combining organic light-emitting layers that emit blue (B) light and yellow (Y) light, respectively. The functional layer 35 is formed in common across the light-emitting pixels 20B, 20G and 20R.

Here, in the organic EL element 30, by adopting the optical resonance structure between the reflective electrode 16 as a reflective layer and the cathode 36 as a semi-transmissive reflective layer, light is emitted at a stronger brightness in resonance wavelengths corresponding to the light emitted in the colors of B, G and R.

The resonance wavelength for each of the light-emitting pixels 20B, 20G and 20R in the optical resonance structure is determined based on the optical distance between the reflective electrode 16 and the cathode 36 and, specifically, is set to satisfy the following Equation (1). Hereinafter, the optical distance is referred to as an optical path length D.

Optical path length D={(2πm+φL+φU)/4π}λ (1)

where m is a positive integer, φL is the phase shift in reflection at the reflective electrode 16, φU is the phase shift in reflection at the cathode 36, and λ is the peak wavelength of the standing wave.

The optical distance of each layer in the optical resonance structure is represented by the product of the thickness of each layer through which light is transmitted and the refractive index.

Equation (1) is a basic equation for when the principal ray is oriented in a direction perpendicular to the display surface and does not assume a case where the principal ray is tilted. In particular, when the angle of view is increased in a downsized display device, the angle of the principal ray increases at peripheral edge portions of the display area and the optical path length increases. As a result, a shift in chromaticity occurs. In light of this, the present inventors have devised an adjustment method for optical path length in accordance with Equation (1), taking into account the angle of view. Prior to a specific description of the adjustment method, problems of the related art will be described.

Angle of View and Adjustment Layer

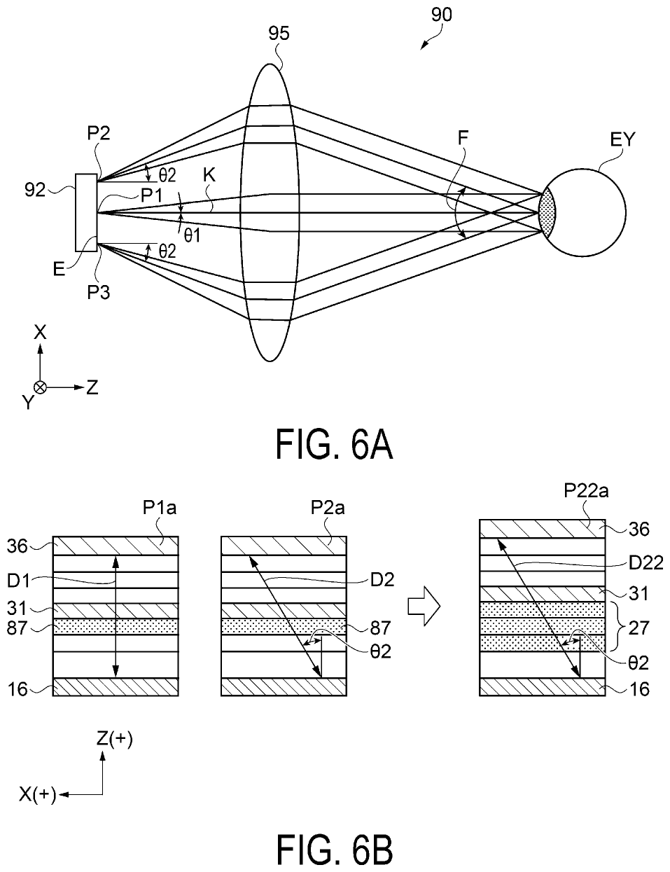

FIG. 6A is a schematic diagram illustrating an optical system of an apparatus that displays a virtual image. FIG. 6A is a side view of an optical system 90 when viewed along the direction of travel of image light. FIG. 6B is a schematic cross-sectional view of a sub-pixel.

The optical system 90 is an optical system that can be provided in a camera viewfinder or an HMD. In the present embodiment, the optical system 90 will be described as an optical system of an HMD.

The optical system 90 includes a display device 92 and an eyepiece 95. The display device 92 is an organic EL panel and has a planar size smaller than the planar area of the eyepiece 95. This is due to the fact that the HMD is to mounted on a head and is required to be small and lightweight for comfortable wear. The eyepiece 95 is a convex lens.

The image displayed on the display device 92 is magnified by the eyepiece 95 and is incident on an eye EY as image light. The image light is a luminous flux centered on an optical axis K that extends perpendicularly from the center of the display surface E of the display device 92. As illustrated in FIG. 6A, the image light expands from the display surface E at a wide angle to converge at the eyepiece 95 and enter the eye EY. The optical axis K is a straight line that passes through the center of the eyepiece 95 from the center of the display surface E to the center of the eye EY.

The eye EY is shown a virtual image formed by the image light that is magnified by the eyepiece 95. Note that various other lenses, light guides and other components may be provided between the eyepiece 95 and the eye EY.

In this optical system, an angle of view F needs to be increased in order to obtain a large virtual image. In order to increase the angle of view F by using the display device 92, which has a smaller planar area than the eyepiece 95, the angle of the principal ray needs to be increased.

The principal ray will now be described. The principal ray is, among the luminous flux emitted from the pixel, the central axis of luminous flux that are primarily used in the applicable optical system. For example, in a sub-pixel P1 located substantially at the center of the display surface E, the principal ray is light along the optical axis K and an angle θ1 at which the principal ray is tilted is approximately 0°. Similarly, in a sub-pixel P2 located at an end portion of the display surface E in the +X direction, the principal ray is tilted at an angle θ2 that expands outward of the optical axis K. Similarly, in a sub-pixel P3 located at an end portion of the display surface E in the −X direction, the principal ray is tilted at the angle θ2 that expands outward of the optical axis K on a side opposite to the sub-pixel P2. Note that the angle θ2 depends on the application but is generally from 10° to 25°.

Thus, in order to increase the angle of view F by using a small display device 92, the angles of the principal rays of sub-pixels located closer to end portions of the display surface need to be increased. When increasing the angles of the principal rays, there is a problem in that chromaticity shift occurs when the display device 92 is regarded as a typical display device.

A cross-sectional view P1a in FIG. 6B is a schematic cross-sectional view illustrating the sub-pixel P1 substantially at the center of the display surface E. Because the angle θ1 of the principal ray is approximately 0° in the sub-pixel P1, an optical path length D1 of the resonance structure is set to a length corresponding to when one adjustment layer 87 for optical path length is provided based on a basic formula. In the sub-pixel P1, chromaticity shift does not occur. Note that the sub-pixels P1, P2 and P3 are described as green pixels.

On the other hand, as illustrated in the cross-sectional view P2a in FIG. 6B, in the sub-pixel P2 located at the end portion of the display surface E, the optical path length is an optical path length D2 longer than the optical path length D1 because the angle θ2 of the principal ray is larger than the angle θ1 but the optical path length is set the same as the sub-pixel P1. Thus, to create an optical path length setting that satisfies an optical resonance condition with the optical path length D1, the principal ray is tilted to achieve the optical path length D2, and causing a color shift due to resonating at a wavelength different to that of a target wavelength.

In light of this, the organic EL device 100 according to the present embodiment adopts an adjustment method for optical path length that takes into account the angle of view.

A cross-sectional view P22a in FIG. 6B is a schematic cross-sectional view illustrating a sub-pixel P22 located at an end portion of the display surface E in the organic EL device 100. Note that the organic EL device 100 and the display device 92 are the same size, and that the sub-pixel P22 corresponds to the sub-pixel P2.

The angle 82 of the principal ray of the sub-pixel P22 is the same as that of the sub-pixel P2, but chromaticity shift is suppressed by providing three adjustment layers 27 for adjusting optical path length to increase the optical path length so as to satisfy an optical resonance condition. Specifically, by increasing the number of the adjustment layers 27 and setting the optical path length to an optical path length D22 that is longer than the optical path length D2, it is possible to satisfy an optical resonance condition even at peripheral edge portion of the display surface E.

As a result, light emitted from the sub-pixel P22 as a second sub-pixel at the predetermined tilt angle θ2 has the adjusted optical path length D22 and is therefore green light that satisfies an optical resonance condition. The same applies to red and blue light. In the optical system 90 of FIG. 6A, employing the organic EL device 100 according to the present embodiment as the display device 92 achieves effects such as increasing the angle of view F and reducing the size of the optical system 90. Details of the adjustment method for optical path length will be described later.

Correlation Between Principal Ray Angle and Adjustment Layer Thickness

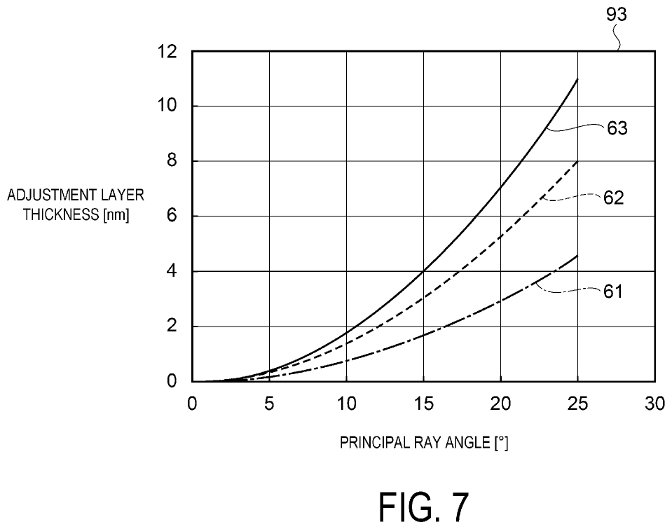

FIG. 7 is a graph showing correlation between principal ray angle and adjustment layer thickness. In graph 93, the horizontal axis represents the angle)(°) of the principal ray and the vertical axis represents the thickness (nm) of the adjustment layer.

The graph 93 is a simulation of the correlation between the principal ray angle and adjustment layer thickness based on the material, thickness and other factors of each layer in accordance with Expression 1.

A line segment 61 indicates the correlation between the angle of the principal ray in a blue sub-pixel and the thickness of the adjustment layer required to achieve an appropriate optical path length for optical resonance at that angle. As indicated by the line segment 61, it is understood that the adjustment layer thickness exhibits quadratic growth as the principal ray angle increases.

A line segment 62 indicates correlation in a green sub-pixel. Similar to blue, the adjustment layer thickness exhibits quadratic growth as the principal ray angle increases, but the slope is greater than that of blue. In other words, it was found that the adjustment layer needs to be thicker in a green sub-pixel than in a blue sub-pixel.

A line segment 63 represents correlation in a red sub-pixel. Similar to green, the adjustment layer thickness exhibits quadratic growth as the principal ray angle increases, but the slope is greater than that of green. In other words, it was found that the adjustment layer needs to be thicker in a red sub-pixel than in a green sub-pixel.

In summary, it is understood that an optical resonance condition can be satisfied even at peripheral edge portions of the display surface E by adjusting the adjustment layer thickness according to the principal ray angle in each of the color sub-pixels.

The adjustment method for optical path length according to the present embodiment is based on the correlation between the principal ray angle and the adjustment layer thickness in the graph 93.

Adjustment Method for Optical Path Length

In the adjustment method for optical path length according to the present embodiment, the display region E is divided into a plurality of areas and the optical path length is adjusted for each area according to the number of stacked adjustment layers. The plurality of areas are divided according to, for example, the degree of tilt of the principal ray, the display size and the application.

When n is the total number of areas in the display region E that has been divided into a plurality of areas and m is an area to be adjusted, the number of adjustment layers for each color light emitted from the sub-pixels in the target area m is determined by the following Equations (2) to (4).

Number of adjustment layers in blue sub-pixel:B(n,m)=m− 1(2)

Number of adjustment layers in green sub-pixel:G(n,m)=n+m−1 (3)

Number of adjustment layers in red sub-pixel:R(n,m)=2n+m−1 (4)

provided that n≥m.

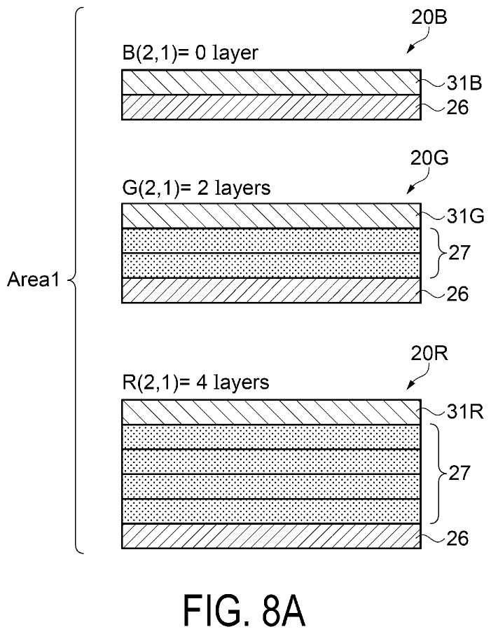

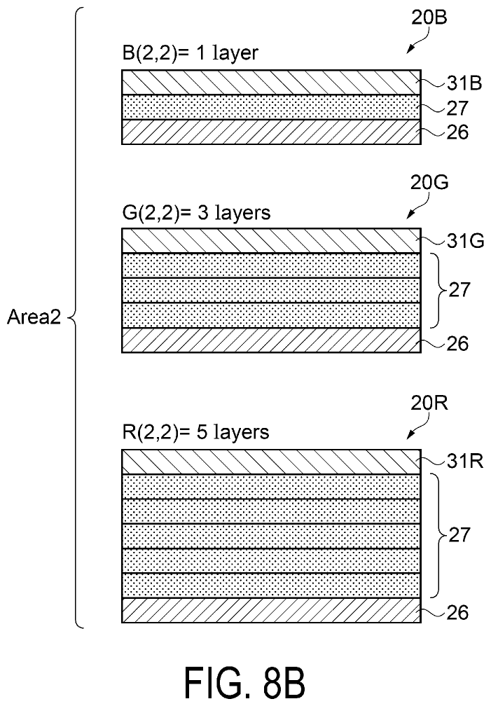

FIG. 8A is a diagram illustrating the number of adjustment layers in each color sub-pixel in the reference area. FIG. 8B is a diagram illustrating the number of adjustment layers in each color sub-pixel in a peripheral area.

Here, an example of a specific adjustment method for optical path length will be described with reference to FIG. 1.

As illustrated in FIG. 1, the display region E of the organic EL device 100 is divided into two areas. The center of the display region E is an area A1, and either side of the area A1 in the X direction is an area A2. Thus, the total number of areas n is 2.

First, the target area m in the reference area A1 is 1, and thus the number of adjustment layers is calculated based on the Equations (2) to (4).

Number of adjustment layers in blue sub-pixel:B(2,1)=1−1=0 layers

Number of adjustment layers in green sub-pixel: G(2,1)=2+1−1=2 layers

Number of adjustment layers in red sub-pixel:R(2,1)=2×2+1−1=4 layers

FIG. 8A is a cross-sectional view of a main portion illustrating an example of forming the adjustment layers in each color sub-pixel in the area A1 based on the calculation results.

In the blue light-emitting pixel 20B, no adjustment layer is provided between the second protective layer 26 and the pixel electrode 31B and thus the pixel electrode 31B is formed on the second protective layer 26.

In the green light-emitting pixel 20G, two adjustment layers 27 are formed between the second protective layer 26 and the pixel electrode 31G.

In the red light-emitting pixel 20R, four adjustment layers 27 are formed between the second protective layer 26 and the pixel electrode 31R.

FIG. 5B is a table of examples of thicknesses of an adjustment layer and associated layers. Table 39 in FIG. 5B shows examples of the thickness of the adjustment layer 27 and associated layers related to the resonance structure in area A1 and corresponds to FIG. 5A.

Here, the thickness of the adjustment layer 27 and the associated layers in a preferred example will be described. Table 39 shows examples of the material, refractive index and thickness of each of portion in the preferred example. Note that the materials and numbers are not limited to those shown and may be set as appropriate according to the application of the organic EL device 100, specifications including the size, and other factors.

As shown in Table 39, the thickness of the adjustment layer 27 in the preferred example is 50 nm.

In the blue light-emitting pixel 20B, the adjustment layer is not provided based on the calculated result of Equation (2). In the green light-emitting pixel 20G, two adjustment layers 27 are formed based on the calculated result of Equation (3), and the total thickness is 100 nm.

In the red light-emitting pixel 20R, four adjustment layers 27 are formed based on the calculated result of Expression (4), and the total thickness is 200 nm. Note that the same applies to area A2 except that the number of the adjustment layers 27 is different.

A description is given with reference to FIG. 8B.

Similar to the area A1, the target area m in the area A2 is 2, and thus the number of adjustment layers is calculated based on the Equations (2) to (4).

Number of adjustment layers in blue sub-pixel:B(2,2)=2−1=1 layer

Number of adjustment layers in green sub-pixel:G(2,2)=2+2−1=3 layers

Number of adjustment layers in red sub-pixel: R(2,2)=2×2+2−1=5 layers

FIG. 8B is a cross-sectional view of a main portion illustrating an example of forming adjustment layers in each of the color sub-pixels in the area A2 based on the calculation results.

In the blue light-emitting pixel 20B, one adjustment layer 27 is formed between the second protective layer 26 and the pixel electrode 31B.

In the green light-emitting pixel 20G, three adjustment layers 27 are formed between the second protective layer 26 and the pixel electrode 31G.

In the red light-emitting pixel 20R, five adjustment layers 27 are formed between the second protective layer 26 and the pixel electrode 31R.

As described above, in a case where the total number of areas n is 2, the number of the adjustment layers 27 is divided into 0 to 5 layers across the two areas. In other words, an appropriate number of adjustment layers must be formed separately for each area and for each sub-pixel. Next, a method for manufacturing the adjustment layer will be described.

Method for Manufacturing Adjustment Layer

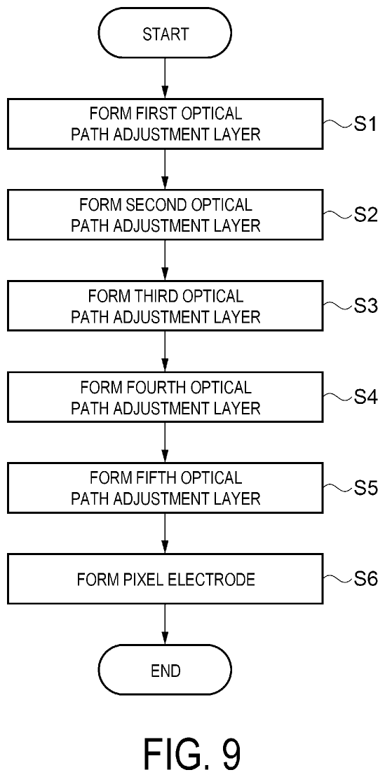

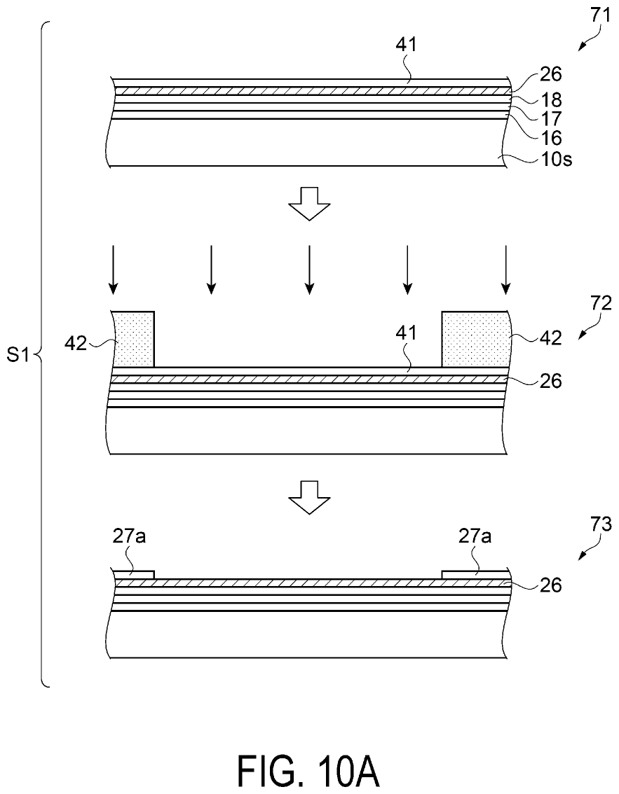

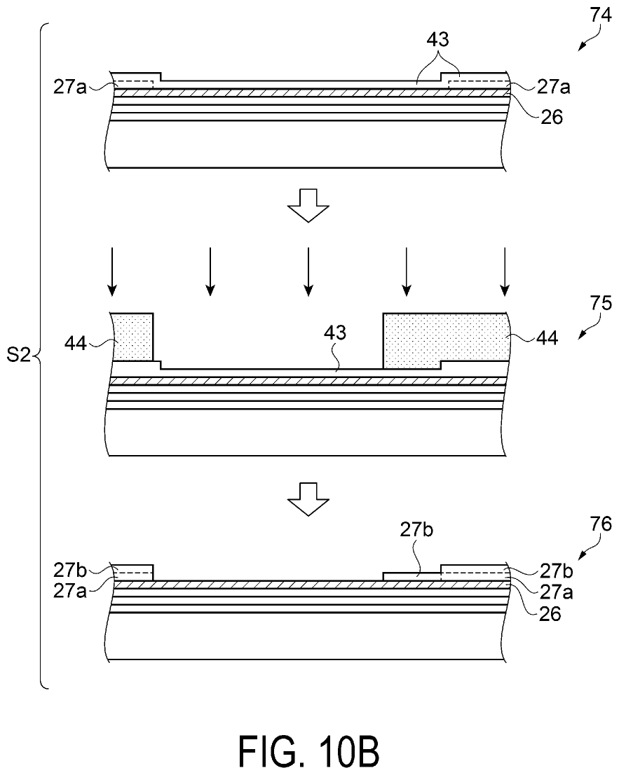

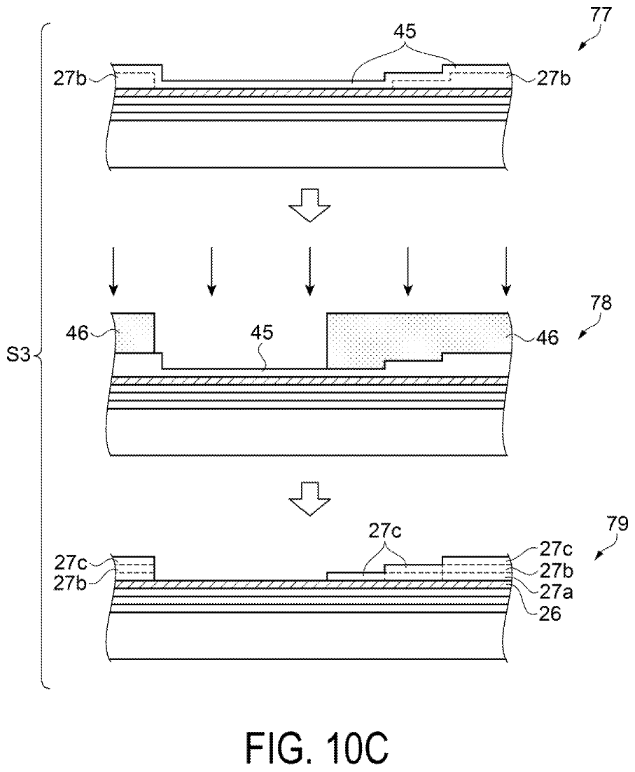

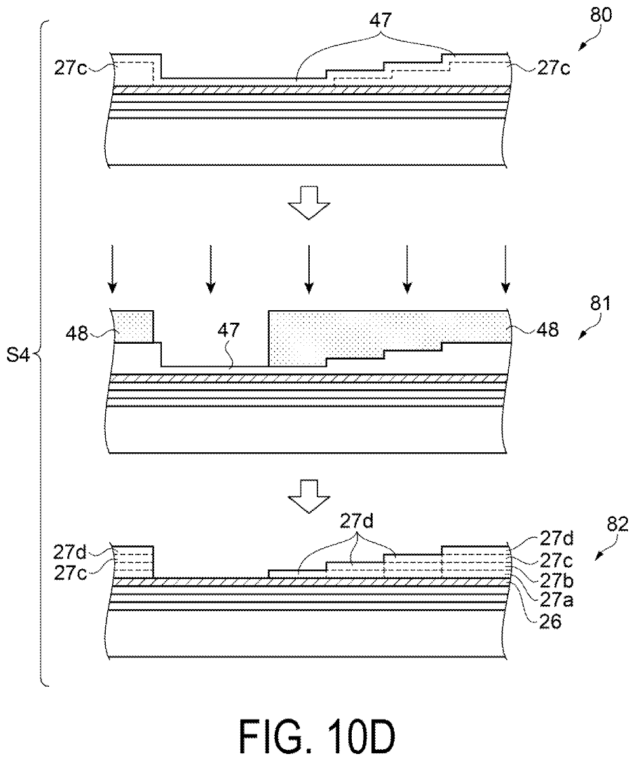

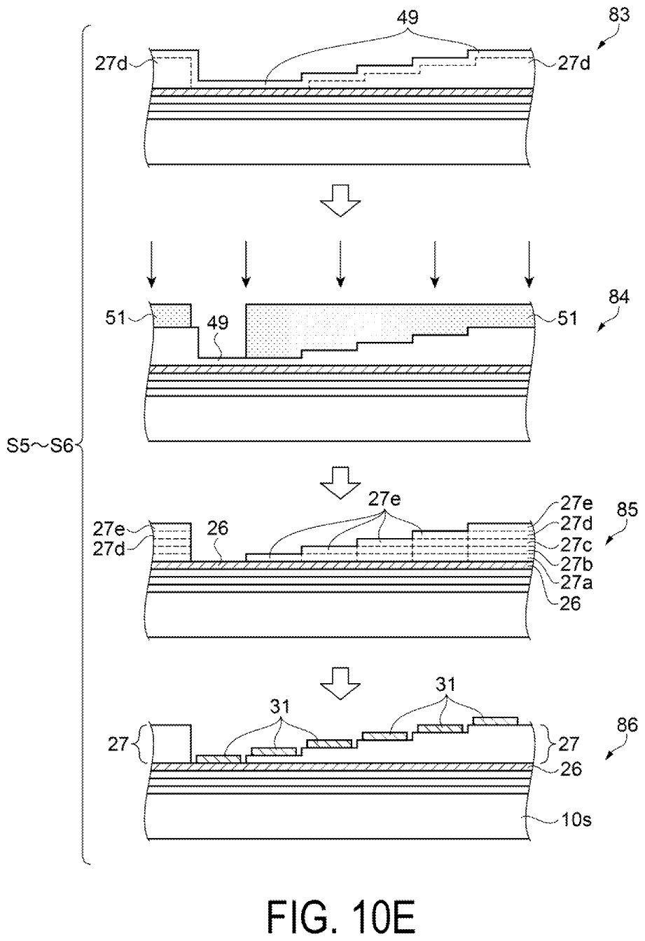

FIG. 9 is a process flow chart illustrating a flow of manufacturing an adjustment layer. FIGS. 10A to 10E are cross-sectional views illustrating the manufacturing process in different steps.

Here, a manufacturing method for separately forming the adjustment layer in six stages from 0 to 5 layers is described with reference to FIG. 9 and FIGS. 10A to 10E. Note that, as illustrated in the process diagram 85 in FIG. 10E for explaining the step, a completed state is a state where the adjustment layer has been gradually formed in order from 0 to 5 layers. However, in practice, the adjustment layer is formed by setting a resist opening to achieve the number of layers calculated for each sub-pixel in each area.

First, the process diagram 71 in FIG. 10A illustrates a case where each layer until the second protective layer 26 that serves as the foundation of the adjustment layer is formed on the base material 10s. The second protective layer 26 is a flat silicon nitride layer formed on the first protective layer 18.

In Step S1, a first adjustment layer 27a is formed. First, a material layer 41 is formed to fill spaces on the entire surface of the second protective layer 26. The material layer 41 is a silicon oxide layer and is formed in a preparation step before etching is performed. The material layer 41 is formed using CVD, for example. The process diagram 71 illustrates a state where the material layer 41 is formed.

Next, a photosensitive resist layer is formed to fill spaces on the entire surface of the material layer 41. Then, as in the process diagram 72, the resist layer is exposed and developed to form a resist pattern having a predetermined opening. The resist pattern having a predetermined opening is a resist mask 42.

Next, the resist mask 42 and the material layer 41 are subjected to dry etching. Specifically, the material layer 41 exposed through the opening via the resist mask 42 is dry-etched by using, for example, a fluorine-based treatment gas. At this time, the second protective layer 26 formed of silicon nitride functions as an etch stopper because the second protective layer 26 has a slower etching rate in dry etching than the silicon oxide of the material layer 41. In other words, this difference in etching selectivity is used to make the second protective layer 26 an etch stop film for dry etching. As a result, the adjustment layer 27a is formed on the second protective layer 26 as illustrated in the process diagram 73.

In Step S2, a second adjustment layer 27b is formed. A material layer 43 is formed to fill spaces on the entire surfaces of the adjustment layer 27a and the second protective layer 26. The material layer 43 is a silicon oxide layer and is formed using the same method as the material layer 41. The process diagram 74 in FIG. 10B illustrates a state where the material layer 43 is formed.

Next, a photosensitive resist layer is formed to fill spaces on entire surface of the material layer 43. Then, as illustrated in the process diagram 75, the resist layer is exposed and developed to form a resist mask 44 having a predetermined opening.

Next, the resist mask 44 and the material layer 43 are subjected to dry etching. Specifically, the second protective layer 26 is dry-etched as an etch stop film, similar to in Step S1, with respect to the material layer 43 exposed through the opening via the resist mask 44. As a result, as illustrated in process diagram 76, the adjustment layer 27b is formed on the adjustment layer 27a and a portion of the second protective layer 26.

In Step S3, a third adjustment layer 27c is formed. A material layer 45 is formed to fill spaces on the entire surfaces of the adjustment layer 27b and the second protective layer 26. The material layer 45 is a silicon oxide layer and is formed using the same method as the material layer 41. The process diagram 77 in FIG. 10C illustrates a state where the material layer 45 is formed.

Next, a photosensitive resist layer is formed to fill spaces on the entire surface of the material layer 45. Then, as illustrated in the process diagram 78, the resist layer is exposed and developed to form a resist mask 46 having a predetermined opening.

Next, the resist mask 46 and the material layer 45 are subjected to dry etching. Specifically, the second protective layer 26 is dry-etched as an etch stop film, similar to in Step S1, with respect to the material layer 45 exposed through the opening via the resist mask 46. As a result, as illustrated in process diagram 79, the adjustment layer 27c is formed on the adjustment layer 27b and a portion of the second protective layer 26.

In Step S4, a fourth adjustment layer 27d is formed. A material layer 47 is formed to fill spaces on the entire surfaces of the adjustment layer 27c and the second protective layer 26. The material layer 47 is a silicon oxide layer and is formed using the same method as the material layer 41. The process diagram 80 in FIG. 10D illustrates a state where the material layer 47 is formed.

Next, a photosensitive resist layer is formed to fill spaces on the entire surface of the material layer 47. Then, as illustrated in the process diagram 81, the resist layer is exposed and developed to form a resist mask 48 having a predetermined opening.

Next, the resist mask 48 and the material layer 47 are subjected to dry etching. Specifically, the second protective layer 26 is dry-etched as an etch stop film, similar to in Step S1, with respect to the material layer 47 exposed through the opening via the resist mask 48. As a result, as illustrated in process diagram 82, the adjustment layer 27d is formed on the adjustment layer 27c and a portion of the second protective layer 26.

In Step S5, a fifth adjustment layer 27e is formed. A material layer 49 is formed to fill spaces on the entire surfaces of the adjustment layer 27d and the second protective layer 26. The material layer 49 is a silicon oxide layer and is formed using the same method as the material layer 41. The process diagram 83 in FIG. 10E illustrates a state where the material layer 49 is formed.

Next, a photosensitive resist layer is formed to fill spaces on the entire surface of the material layer 49. Then, as illustrated in the process diagram 84, the resist layer is exposed and developed to form a resist mask 51 having a predetermined opening.

Next, the resist mask 51 and the material layer 49 are subjected to dry etching. Specifically, the second protective layer 26 is dry-etched as an etch stop film, similar to in Step S1, with respect to the material layer 49 exposed through the opening via the resist mask 51. As a result, as illustrated in process diagram 85, the adjustment layer 27e is formed on a portion of the second protective layer 26 and the adjustment layer 27d. With the processes described above, a 0-layer portion where the second protective layer 26 is exposed and the 1 to 5 adjustment layers are selectively formed separately.

In Step S6, the pixel electrode 31 is formed. As illustrated in the process diagram 86, a transparent electrode film is formed through sputtering on the adjustment layer 27e and the second protective layer 26 and patterned to form the pixel electrode 31 on the exposed portion of the second protective layer 26 and the 1- to 5-layer portions of the adjustment layer 27. ITO is used as the material of the pixel electrode 31.

To facilitate explanation, a description has been given of a configuration where the adjustment layer is gradually formed in order from 0 to 5 layers but, in practice, the adjustment layer is formed by setting the resist opening to achieve the number of layers calculated for each sub-pixel in each area. For example, in the case of FIG. 8A, in the adjacent blue, green and red sub-pixels, adjustment layers are formed in the order of 0 layers, 2 layers and 4 layers. Similarly, in the case of FIG. 8B, in the adjacent blue, green and red sub-pixels, adjustment layers are formed in the order of 1 layer, 3 layers and 5 layers.

Effect of Area Division on Optical Path Length Setting

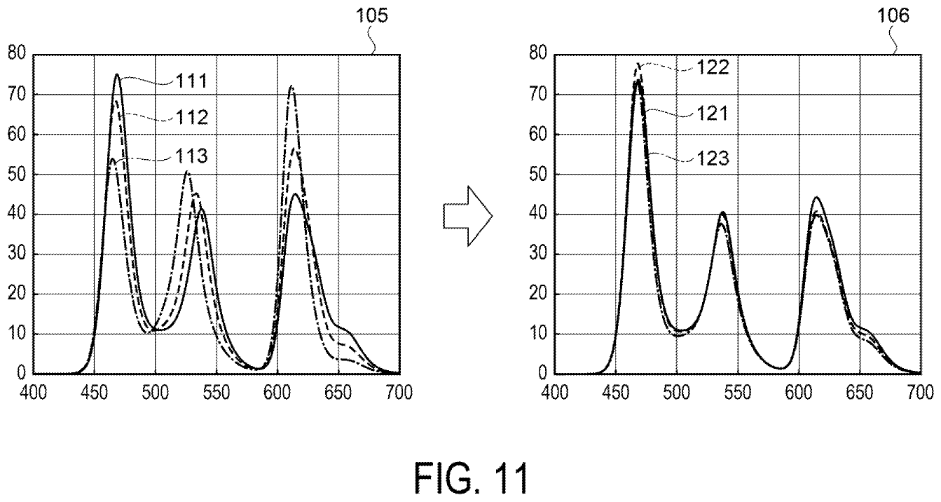

FIG. 11 is a graph showing the distribution of intensity of the wavelength component for each area. Graph 105 shows the optical spectrum of a typical display device, and graph 106 illustrates the optical spectrum according to optical path length setting in the present embodiment. Both graphs show results of simulation by the present inventors. In the graphs 105 and 106, the horizontal axis represents the wavelength of light (nm) and the vertical axis represents light intensity (a.u.). As a simulation condition, the total number of areas n was 3. The angle of the principal ray in the reference area A1 of the display area was 0°, the angle of the principal ray in the area A2 outside the area A1 was 15°, and the angle of the principal ray in an area A3 outside the area A2 was 25°. Note that these spectra indicate the spectrum of white light emitted from the optical resonance structure of a representative sub-pixel in each area.

As shown in graph 105, in a typical display device, a spectrum shift occurs in an area where the angle of the principal ray is large, and this causes color shift to occur. Specifically, near 470 nm, which is the peak of blue light, a line segment 112 indicating the spectrum of the outer area A2 shifts further toward a side on which the peak value has a short wavelength than a line segment 111 indicating the spectrum of the reference area A1. Similarly, the peak value of a line segment 113 indicating the spectrum of an area A3 shifts further toward a shorter wavelength side than the line segment 112 of the area A2. The same applies to green light and red light.

That is, in a typical display device, colored light shifts toward the short wavelength side and chromaticity is more likely to change as the area where the principal ray angle is large increases.

In contrast, with a configuration based on the adjustment method for optical path length according to the present embodiment, as shown in graph 106, the spectra of the three areas substantially overlap and no color shift is observed. Specifically, near 470 nm, which is the peak of blue light, a line segment 121 indicating the spectrum of the reference area A1 and a line segment 122 indicating the spectrum of the outer area A2 substantially overlap and no shift in the peak value is observed. Similarly, a line segment 123 indicating the spectrum of the area A3 and the line segment 121 of the area A1 substantially overlap. In other words, the wavelength range of light emitted from a blue sub-pixel in the area A3 at a predetermined tilt angle of 25° is considered to substantially match the wavelength range of light emitted from a blue sub-pixel in the vertical direction in the area A1. The wavelength range of light emitted from a blue sub-pixel in the area A2 at a principal ray angle of 15° substantially matches the wavelength range of light emitted from a blue sub-pixel in the area A1 at a principal ray angle of 0°.

Similarly, near 540 nm, which is the peak of green light, the line segment 121 indicating the spectrum of the reference area A1 and the line segment 122 indicating the spectrum of the outer area A2 substantially overlap and no shift in the peak value is observed. Similarly, the line segment 123 indicating the spectrum of the area A3 also substantially overlaps the line segment 121 of the area A1. In other words, the wavelength range of light emitted from a green sub-pixel in the area A3 at a predetermined tilt angle of 25° substantially matches the wavelength range of light emitted from a green sub-pixel in the vertical direction in the area A1. The wavelength range of light emitted from a green sub-pixel in the area A2 at a principal ray angle of 15° substantially matches the wavelength range of light emitted from a green sub-pixel in the area A1 at a principal ray angle of 0°.

Similarly, near 620 nm, which is the peak of red light, the line segment 121 indicating the spectrum of the reference area A1 and the line segment 122 indicating the spectrum of the outer area A2 substantially overlap and no shift in the peak value is observed. Similarly, the line segment 123 indicating the spectrum of the area A3 also substantially overlaps the line segment 121 of the area A1. In other words, the wavelength range of light emitted from a red sub-pixel in the area A3 at a predetermined tilt angle of 25° substantially matches the wavelength range of light emitted from a red sub-pixel in the vertical direction in the area A1. The wavelength range of light emitted from a red sub-pixel in the area A2 at a principal ray angle of 15° substantially matches the wavelength range of light emitted from a red sub-pixel in the area A1 at a principal ray angle of 0°.

In other words, with a configuration based on the adjustment method for optical path length according to the present embodiment, it is found that chromaticity does not change in the area where the principal ray angle is large.

Note that in the present embodiment, the first sub-pixel and the second sub-pixel are green sub-pixels. At this time, a first wavelength range is a range of from 495 nm to 570 nm, which is the approximate wavelength range of green light. The first sub-pixel and the second sub-pixel are not limited to a green sub-pixel and may be a blue sub-pixel or a red sub-pixel. When adopting blue sub-pixels, the first wavelength range is a range of from 430 nm to 495 nm, which is the approximate wavelength range of blue light. When adopting red sub-pixels, the first wavelength range is a range of from 580 nm to 750 nm, which is the approximate wavelength range of red light.

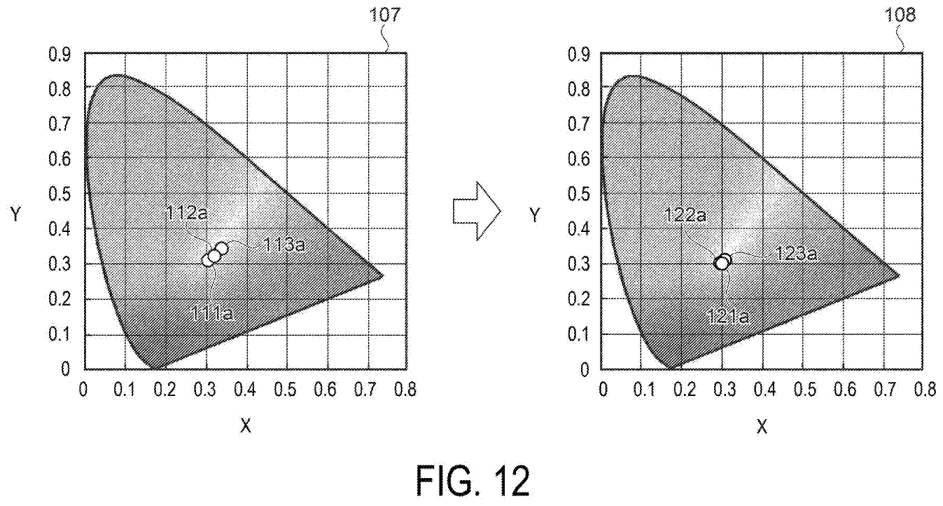

FIG. 12 shows XY chromaticity diagrams illustrating the chromaticity of a representative sub-pixel for each area. Graph 107 shows chromaticity in a typical display device and graph 108 shows chromaticity with an optical path length setting according to the present embodiment. Both graphs are results of simulation conducted by the present inventors. FIG. 12 corresponds to FIG. 11, where graph 107 corresponds to graph 105 and graph 108 corresponds to graph 106. The simulation condition is also identical to that in FIG. 11.

As shown in graph 107, in a typical display device, chromaticity shift occurs in an area where the principal ray angle is large. Specifically, a point 112a indicating chromaticity in the outer area A2 shifts toward the positive side of the XY coordinate, with a point 111a indicating chromaticity in the reference area A1 as a reference. Similarly, the peak value of a point 113a indicating chromaticity in the area A3 shifts further toward the positive side of both the X and Y coordinates than the point 112a of the area A2.

That is, in a typical display device, color light shifts to the short wavelength side and chromaticity changes as the area where the principal ray angle is large increases.

In contrast, when adopting a configuration based on the adjustment method for optical path length according to the present embodiment, as shown in graph 108, chromaticity of the three areas substantially overlap and no color shift is observed. Specifically, a point 121a indicating chromaticity of the reference area A1, a point 122a indicating chromaticity of the outer area A2, and a point 123a indicating chromaticity of the outer area A3 substantially overlap.

In other words, according to the configuration based on the adjustment method for optical path length according to the present embodiment, it is found that chromaticity does not change even in an area where the principal ray angle is large. As a result of verification by the present inventors based on these simulation results, employing the adjustment method for optical path length according to the present embodiment makes it possible to improve change in chromaticity by approximately 8% as compared to a typical display device.

### Effects of First Embodiment

As described above, according to the organic EL device 100 and the manufacturing method thereof, the following effects can be obtained.

In the adjustment method for optical path length in a resonance structure, the display region is divided into a plurality of display areas based on the degree of tilt of the principal ray, display size, application, and other factors. Then, the optical path length in each of the plurality of display areas is adjusted according to the number of stacked adjustment layers calculated based on the Equations (2) to (4). As a result, the optical path length can be adjusted so that an optical resonance condition in a desired wavelength is satisfied even in areas where the principal ray is tilted. Specifically, the optical path length in a display area different to a reference display area is adjusted to be longer than the optical path length in the reference area.

Therefore, unlike a typical display device in which the optical path length becomes longer when the principal ray tilts and the resonance wavelength shifts to cause a change in chromaticity, the organic EL device 100 makes it possible to, because the optical path length is optimized based on the number of stacked adjustment layers, obtain a sharp image in which change in chromaticity is suppressed even in sub-pixels where the principal ray angle is large.

In a typical display device, when a display device that has a smaller planar size than the eyepiece is used, the angle of view increases and, in particular, a change in chromaticity occurs at the edges of the display area. In contrast, with the organic EL device 100, the optical path length can be optimized, and hence a change in chromaticity can be suppressed and sufficient visual field angle characteristics can be ensured even at edges of the display area. Specifically, adjustment is performed so as to increase the optical path length in display areas closer to peripheral edges at which the principal ray angle is large.

Even when the organic EL device 100 is smaller than the eyepiece and a large angle of view setting is used, the optical path length can be optimized throughout the display area, and it possible to meet the need for downsizing. In other words, an organic EL device 100 having a small size and excellent visual field angle characteristics can be provided.

### 2. Second Embodiment

### Division of Display Area

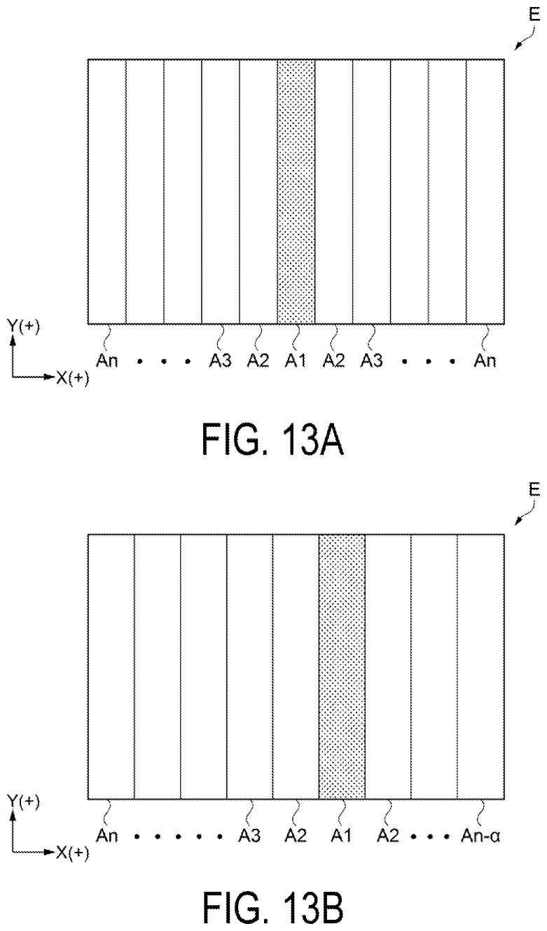

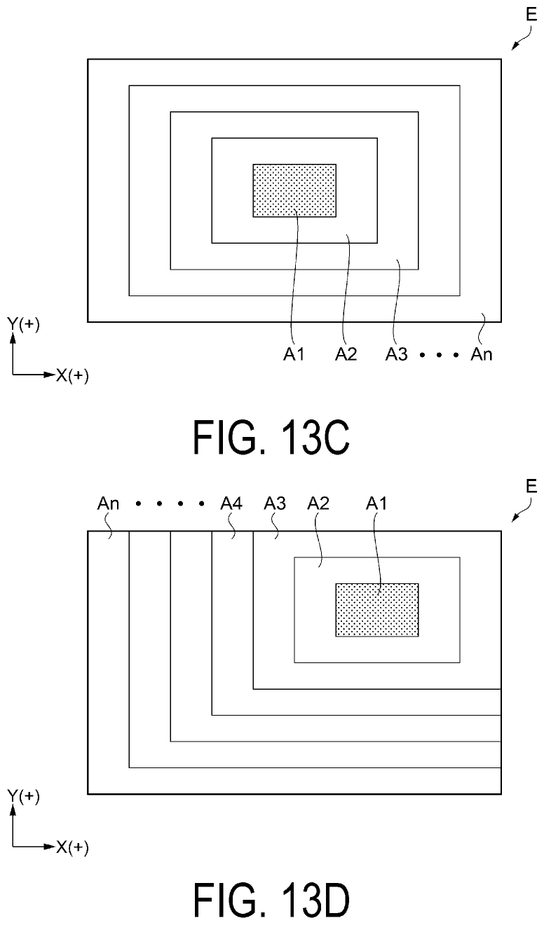

FIGS. 13A to 13D are diagrams illustrating divided display areas.

The first embodiment deals with an exemplary case where the display region is divided into two areas, but the present disclosure is not limited to this configuration and the display region may be divided into a plurality of areas. The same components as in the first embodiment are given the same reference signs, and redundant descriptions of these components will be omitted. Note that in the following description, the X direction is horizontal, the Y direction is vertical, the +X direction is right, the −X direction is left, the +Y direction is up and the −Y direction is down.

In FIG. 13A, the display region E of the organic EL device 100 is divided into n areas each having a vertical stripe shape. Specifically, with a center area of the display region E in the X direction defined as an area A1, the display region E is divided until an area An in the order of an area A2, an area A3 in the +X direction. The width of each area in the X direction is the same. Similarly, in the −X direction, the display region is divided from the area A1 serving as the reference area until an area An in the order of the area A2 and the area A3.

That is, individual areas are formed in vertical stripe shapes to the left and right of the area A1 until the area n.

Even when dividing the display region as described above, the Expressions (2) to (4) of the first embodiment can be used to determine the number of adjustment layers for each color light of the sub-pixels in the target area m.

In FIG. 13B, the display region E is divided into n areas each having a vertical stripe shape similar to FIG. 13A, but the position of the area A1 is shifted to the right. Specifically, the area A1 is slightly shifted in the +X direction from approximately the center of the display region E. From the area A1 as the reference area, the display region is divided into until the area An in the order of the area A2 and the area A3 in the −X direction. In the +X direction, the display region is divided from the area A1 until an area An-α.

Even when dividing the display region as described above, the Expressions (2) to (4) of the first embodiment can be used to determine the number of adjustment layers for each color light of the sub-pixels in the target area m.

Note that FIGS. 13A and 13B illustrate a case where the display region E is divided into a plurality of areas each having a vertical stripe shape, but the display region E may be divided into lateral stripe shapes. Similarly, the position of the area A1 in which tilt of the principal ray is small may be shifted from the center of the display region E.

Even when dividing the display region as described above, the Expressions (2) to (4) of the first embodiment can be used to determine the number of adjustment layers for each color light of the sub-pixels in the target area m.

In FIG. 13C, the display region E is divided into n areas each having a rectangular ring shape. Specifically, the display region E is concentrically divided into areas by defining a long rectangular area at substantially the center of the display region E as an area A1, defining an area A2 having a similar rectangular shape around the area A1 that serves as a reference area, defining an area A3 having a similar rectangular shape around the area A2, and so on until an area An. The length between areas may be equal or unequal. Note that the shape of each area may be an ellipse or a circle. If using ellipses or circles, the display region need only be divided into a plurality of areas concentrically.

Even when dividing the display region as described above, the Expressions (2) to (4) of the first embodiment can be used to determine the number of adjustment layers for each color light of the sub-pixels in the target area m.

In FIG. 13D, the display region E is divided into n areas each having a rectangular ring shape similar to FIG. 13C, but the position of the area A1 is shifted to the top right. Specifically, the area A1 is shifted in the +X direction and the +Y direction from approximately the center of the display region E. Thus, similar to in FIG. 13C, the entire circumference of the rectangular shape increases cocentrically with the area A1 as a reference until the area A3, but only the lower side and the left side increase from area A4. From the area A4, the upper side and the right side are fixed so that only the lower side and the left side increase. Note that the shape of each area may be an ellipse or a circle. If using ellipses or circles, the display region need only be divided into a plurality of areas concentrically.

Even when dividing the display region as described above, the Expressions (2) to (4) of the first embodiment can be used to determine the number of adjustment layers for each color light of the sub-pixels in the target area m.

Effects

Even when dividing the display region as described above, the optical path length for each area can be adjusted based on the number of adjustment layers calculated based on the Equations (2) to (4), similar to the first embodiment.

Accordingly, an organic EL device 100 exhibiting less change in chromaticity and excellent visual field angle characteristics can be provided.

In addition, the display region can be divided into a plurality of display areas according to the degree of tilt of the principal ray, display size, application, and the like. Specifically, it is sufficient that a region where the principal ray is substantially perpendicular is defined as the reference area A1, and areas different to the area A1 be divided into a plurality of display areas according to the angle of the principal ray. As illustrated in FIGS. 13C and 13D, the area A1 is not limited to being located at the center of the display region E and can be set to anywhere in the display region E. In particular, the display region is preferably determined depending on the application and according to factors such as the type of HMD (see-through HMD, immersive HMD, etc.) and the differences between users such as gender and age.

### 3. Third Embodiment

### Method for Manufacturing Second Adjustment Layer

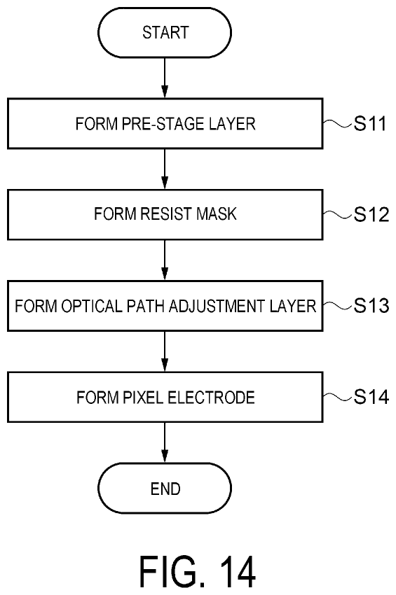

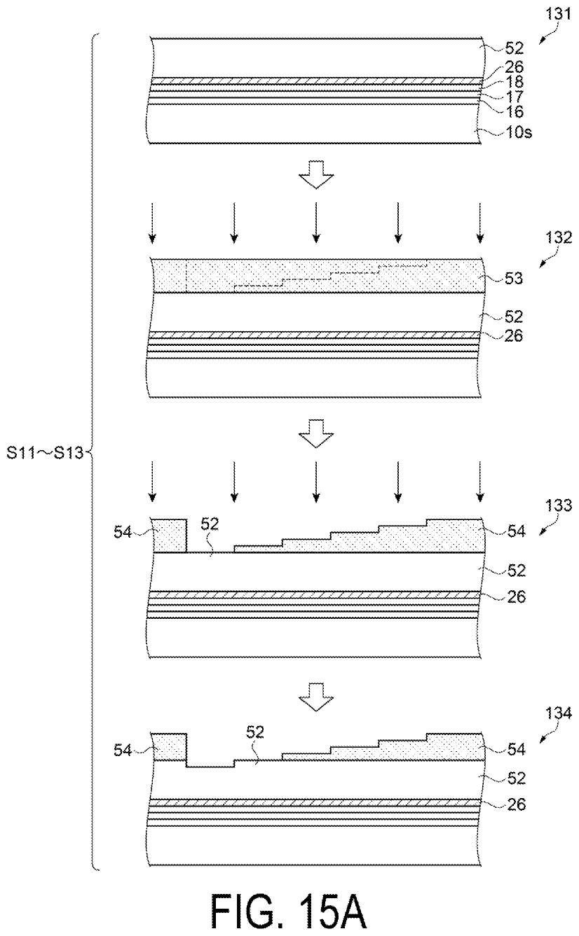

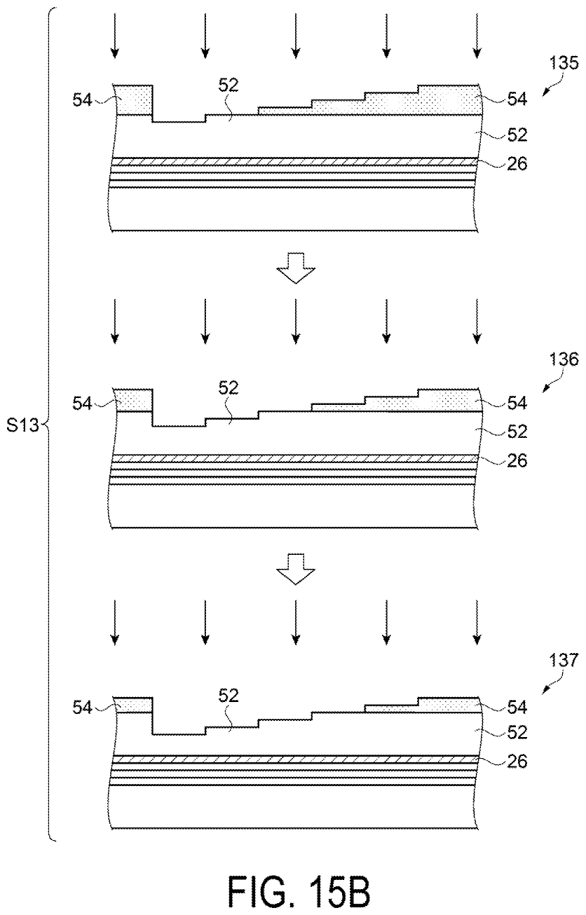

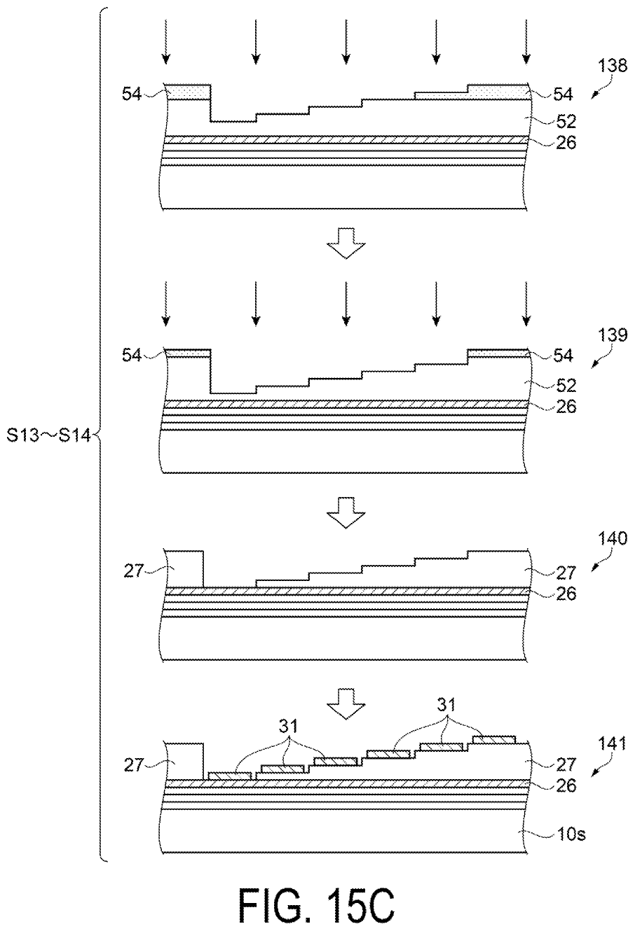

FIG. 14 is a process flow chart illustrating a flow of manufacturing the adjustment layer. FIGS. 15A to 15C are cross-sectional views illustrating manufacturing processes in individual steps.

Here, a method for manufacturing an adjustment layer that is different to the manufacturing method of the first embodiment will be described with reference to FIG. 14 and FIGS. 15A to 15C. The same components as in the first embodiment are given the same reference signs, and redundant descriptions of these components will be omitted.

First, in process diagram 131 in FIG. 15A, layers until the second protective layer 26 that serves as the foundation of the adjustment layer are formed on the base material 10s. The second protective layer 26 is a flat silicon nitride layer formed on the first protective layer 18.

In Step S11, a material layer 52 is formed. The material layer 52 is formed to fill spaces on the entire surface of the second protective layer 26. The material layer 52 is a silicon oxide layer is formed in the same way as in the first embodiment. However, the material layer 52 needs to be formed thick. In particular, the material layer 52 needs to be as thick as five adjustment layers, and thus may be formed multiple times. Further, a flattening treatment may be performed using a Chemical Mechanical Polishing (CMP) method as appropriate. Process diagram 131 illustrates a state where the material layer 52 is formed.

In Step S12, a resist mask 54 is formed. First, a photosensitive resist layer 53 is formed to fill spaces on the entire surface of the material layer 52. Next, the resist layer 53 is subject to gradient exposure with different exposure amounts per region by using a gradient exposure mask. In the process diagram 132, the exposure amount is gradually adjusted such that a portion at which the number of adjustment layers corresponds to 0 layers is most exposed and a portion at which the number of adjustment layers corresponds to 5 layers is least exposed. Note that a gray-tone mask is used as the photo mask for performing gradient exposure. A gray-tone mask is formed with a slit that is less than or equal to the resolution of the exposure device, and intermediate exposure can be performed by blocking a portion of the light. Alternatively, a half-tone mask may be used to perform intermediate exposure utilizing a semi-transmissive film.

The resist mask 54 shown in the process diagram 133 is formed by performing gradient exposure using a gray-tone mask. The difference in the exposure amount causes regions having different thicknesses in six stages to be formed in the resist mask 54. First, a portion where the number of adjustment layers is 0 is an opening. The resist mask 54 gradually becomes thicker from a portion at which the number of adjustment layers corresponds to 1 layer as the number of layers increases and is thickest at the portion at which the number of adjustment layers corresponds to 5 layers.

In Step S13, an adjustment layer for optical path length is formed. The resist mask 54 and the material layer 52 are subjected to dry etching. Specifically, dry etching is performed on the resist mask 54 and the material layer 52 that is exposed through the opening.

As a result, as illustrated in the process diagram 134, the material layer 52 portion exposed through the opening is immersed to a distance corresponding to one adjustment layer. The surface of the resist mask 54 is also immersed to a distance corresponding to one adjustment layer to increase the exposed portion of the material layer 52. Note that the process diagram 134 illustrates a state where the adjustment layer is immersed to a distance corresponding to one layer to facilitate explanation, but in practice, dry etching is performed continuously until the resist mask 54 is eliminated. In other words, dry etching is performed until the shape of the resist mask 54 is transferred to the material layer 52.

As illustrated in process diagram 135 of FIG. 15B, dry etching is continuously performed on the resist mask 54 and the material layer 52 that is exposed through the opening.

As a result, as illustrated in the process diagram 136, the material layer 52 is immersed to a distance corresponding to two adjustment layers. The surface of the resist mask 54 is also immersed to a distance corresponding to one adjustment layer to increase the exposed portion of the material layer 52. Further, as illustrated in the process diagram 137, the material layer 52 is immersed to a distance corresponding to three adjustment layers by continuously performing dry etching. The surface of the resist mask 54 is also immersed to a distance corresponding to one adjustment layer to increase the exposed portion of the material layer 52.

As illustrated in the process diagram 138 of FIG. 15C, dry etching is continuously performed on the resist mask 54 and the material layer 52 that is exposed through the opening.

As a result, as illustrated in the process diagram 139, the material layer 52 is immersed to a distance corresponding to four adjustment layers. The surface of the resist mask 54 is also immersed to a distance corresponding to one adjustment layer to increase the exposed portion of the material layer 52. By continuously performing dry etching, the resist mask 54 is transferred to form the adjustment layer 27 as illustrated in the process diagram 140. At this time, the second protective layer 26 functions as an etch stopper. With the processes described above, a 0-layer portion at which the second protective layer 26 is exposed and the adjustment layer 27 having thicknesses corresponding to 1 layer to 5 layers are selectively formed separately.

In Step S14, the pixel electrode 31 is formed. A transparent electrode film is formed by sputtering on the adjustment layer 27 and the second protective layer 26 and patterned to form the pixel electrode 31 on the exposed portion of the second protective layer 26 and portions of the adjustment layer 27 having thicknesses corresponding to 1 layer to 5 layers as illustrated in process diagram 141. ITO is used as the material for the pixel electrode 31.

Note that, while manufacturing methods differ, the adjustment layer 27 formed by this manufacturing method is made of the same material and has the same shape as the adjustment layer 27 in the process diagram 86 of FIG. 10E according to the first embodiment and thus can be considered equivalent to the adjustment layer 27.

Effects

Even with this manufacturing method, the 0-layer portion at which the second protective layer 26 is exposed and the adjustment layer 27 having thicknesses corresponding to 1 layer to 5 layers can be selectively formed separately, similar to the manufacturing method of the first embodiment.

### 4. Fourth Embodiment

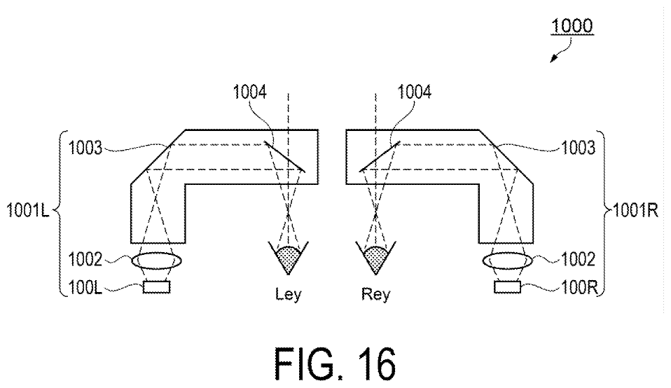

FIG. 16 is a schematic diagram illustrating a head-mounted display as an example of an electronic apparatus.

An HMD 1000 is configured of a pair of optical units 1001L and 1001R used for displaying information corresponding to left and right eyes, respectively, mounting portions corresponding to eyeglass arms, a power supply unit, a control unit, and other components. Note that the mounting portion, the power supply unit and the control unit are not illustrated. Here, the pair of optical units 1001L and 1001R are configured to be horizontally symmetrical, and thus the optical unit 1001R configured for the right eye will be described as an example.

The optical unit 1001R includes a display unit 100R to which the organic EL device 100 of the above-described embodiment is applied, a light-converging optical system 1002 and an L-shaped light guide 1003. A half mirror layer 1004 is provided in the light guide 1003. In the optical unit 1001R, display light emitted from the display unit 100R converges at the light-converging optical system 1002 configured of a convex lens and is then incident on the light guide 1003 and reflected by the half mirror layer 1005 to be guided to a right eye Rey. The display light displays a virtual image in the half mirror layer 1004.

With such a configuration, the wearer of the HMD 1000 views a scene observed through the transparent light guide 1003 and a virtual image displayed on the half mirror layer 1004. In other words, the HMD 1000 is a see-through HMD.

The light guide 1003 is configured by combining rod lenses and forms a rod integrator. The light-converging optical system 1002 and the display unit 100R are arranged on the side of the light guide 1003 where light enters and have a configuration where the display light converged by the light-converging optical system 1002 is received by the rod lenses. Further, the half mirror layer 1004 of the light guide 1003 has an angle that reflects luminous flux toward the right eye Rey. Here, the luminous flux converges at the light-converging optical system 1002 and is totally reflected and transmitted within the rod lenses.

In this embodiment, the planar size of the display unit 100R is set to be smaller than the planar size of the light-converging optical system 1002. In order to obtain a large virtual image in a small display unit 100R, the angle of view needs to be increased. Therefore, in the display unit 100R, the display region is divided into a plurality of areas and optical path lengths are adjusted for each area based on the Equations (2) to (4) described above.

As described above, the optical unit 1001L for the left eye is the same as the optical unit 1001R for the right eye except that the optical unit 1001L includes a display unit 100L to which the organic EL device 100 of the above-described embodiment is applied, and configuration and functions are inverted relative to the optical unit 1001R.

Effects

As described above, the HMD 1000 includes the organic EL device 100 that is compact and has excellent visual field angle characteristics. Thus, a compact HMD 1000 that can achieve a large virtual image and has excellent visual field angle characteristics can be provided.

Note that the HMD 1000 to which the organic EL device 100 of the above-described embodiment is applied is not limited to a configuration including the pair of optical units 1001L and 1001R corresponding to both eyes and may instead include only the optical unit 1001R, for example. The HMD is furthermore not limited to a see-through HMD and may instead be an immersive HMD in which the display is viewed in a state where outside light is shielded.

### 5. Modification Example 1

### Other Method for Manufacturing Adjustment Layer-1

This method will be mainly described with reference to FIG. 15A and reference to FIGS. 14 and 15C as appropriate.

In the embodiments described above, it is described that etching is continuously performed until the shape of the resist mask 54 in the process diagram 133 is transferred to the material layer 52, but the present disclosure is not limited to this configuration. For example, the resist mask 54 may be used as an adjustment layer. Specifically, the resist mask 54 can also be used as an adjustment layer because the resist mask 54 and the adjustment layer 27 have the same shape (refer to process diagram 140 in FIG. 15C). In this case, after forming the resist mask 54 in Step S12 in FIG. 14, the process of forming the pixel electrode in Step S14 need only be performed without performing the step of forming the adjustment layer in Step S13. In other words, the step of etching the resist mask 54 and transferring the resist mask 54 to the material layer 52 in Step S13 is not performed.

According to this method, the resist mask 54 can be used as an adjustment layer. Furthermore, because the step of forming the adjustment layer in step S13 is unnecessary, the number of steps can be reduced. Therefore, cost reduction can be achieved.

### 6. Modification Example 2

### Other Method for Manufacturing Adjustment Layer-2

A description is given with reference to FIG. 10E.

Another method for manufacturing an adjustment layer will be described.

In the adjustment layer in process diagram 85 in FIG. 10E, regions from 1 layer to 5 layers are formed. These regions can also be formed by using an ink-jet method.

Specifically, UV curable ink is selectively discharged from an ink jet head onto a first layer. Then, the first layer of the adjustment layer is cured by being irradiated with ultraviolet light.

Subsequently, the UV curable ink is selectively discharged from the ink jet head into a region of a second layer. Then, the second layer of the adjustment layer is cured by being irradiated with ultraviolet light. This is repeated until the fifth layer to form an adjustment layer similar to the adjustment layer in the process diagram 85.

According to this method, the number of steps and manufacturing cost can be suppressed because a resist mask does not need to be used.

Contents derived from the Embodiments will be described below.

A light-emitting device including a first sub-pixel and a second sub-pixel in a display region, the light-emitting device including a reflective layer, a semi-transmissive reflective layer, and a light-emitting functional layer provided between the reflective layer and the semi-transmissive reflective layer, the light-emitting device further having a resonance structure in which light radiated from the light-emitting functional layer resonates between the reflective layer and the semi-transmissive reflective layer, wherein a wavelength range of light, emitted by the first sub-pixel and the second sub-pixel, from the resonance structure is a first wavelength range, and a distance between the reflective layer and the semi-transmissive reflective layer in the second sub-pixel is greater than a distance between the reflective layer and the semi-transmissive reflective layer in the first sub-pixel.

With this configuration, the optical path length in the optical resonance structure in the second sub-pixel is longer than the optical path length in the first sub-pixel. Here, in the display region, the second sub-pixel is located closer to the peripheral edge than the first sub-pixel. In other words, the optical path length is set to an appropriate optical path length that satisfies the optical resonance in the first wavelength range through setting the optical path length of the second sub-pixel closer to the peripheral edge to be longer than the optical path length of the first sub-pixel near the reference area.

Therefore, the optical path length is optimized even at peripheral edge portions of the display region. Thus, a change in chromaticity can be suppressed and a light-emitting device that ensures sufficient visual field angle characteristics can be provided.

A light-emitting device including a first sub-pixel and a second sub-pixel in a display region, the light-emitting device including a reflective layer, and a semi-transmissive reflective layer, a light-emitting functional layer provided between the reflective layer and the semi-transmissive reflective layer, the light-emitting device further having a resonance structure in which light radiated by the light-emitting functional layer resonates between the reflective layer and the semi-transmissive reflective layer, wherein a wavelength range of light, emitted by the first sub-pixel and the second sub-pixel, from the resonance structure is a first wavelength range, and a wavelength range of light emitted at a predetermined tilt angle from the second sub-pixel matches a wavelength range of light emitted in a vertical direction from the first sub-pixel.

According to this configuration, the optical path length of the resonance structure in the second sub-pixel is adjusted to an appropriate optical path length in the first wavelength range. Here, in the display region, the second sub-pixel is located closer to the peripheral edge than the first sub-pixel. In other words, the optical path length of a second sub-pixel at which the angle of the principal ray closer to the peripheral edge is large is set to be greater than the optical path length of a first sub-pixel at which the angle of the principal ray is small, to thereby set the optical path length to an appropriate optical path length that satisfies the optical resonance in the first wavelength range.

Thus, the optical path length is optimized even at peripheral edge portions of the display region, and hence change in chromaticity can be suppressed and a light-emitting device that ensures sufficient visual field angle characteristics can be provided.

A light-emitting device further including a pixel electrode provided between the reflective layer and the light-emitting functional layer, and an insulating layer provided between the reflective layer and the pixel electrode, wherein the insulating layer includes a first layer formed of a first material, and a second layer formed of a second material, which is different from the first material, and the second layer in the second sub-pixel is thicker than the second layer in the first sub-pixel.

According to this configuration, the optical path length of the second sub-pixel can be made longer than the optical path length of the first sub-pixel by adjusting the thickness of the second layer of the insulating layer in the second sub-pixel.

A light-emitting device in which a first sub-pixel is disposed in a reference area serving as a reference in a display region, and a second sub-pixel is disposed in an area, which is different from the reference area.

According to this configuration, in the display region, optical path length is also optimized in a second sub-pixel located in a display area closer to a peripheral edge and is different to the reference area, and hence change in chromaticity can be suppressed.

An electronic apparatus includes the above-described light-emitting device.

According to this configuration, an electronic apparatus capable of suppressing a change in chromaticity and ensuring sufficient visual field angle characteristics can be provided.

A method for manufacturing a light-emitting device including a reflective layer, an insulating layer, a light-emitting functional layer, a semi-transmissive reflective layer, and moreover having a resonance structure in which light radiated from the light-emitting functional layer resonates between the reflective layer and the semi-transmissive reflective layer, the method including forming a first layer of the insulating layer formed of a first material, forming a first material layer on the first layer using a second material, which is different from the first material, forming a resist mask on the first material layer and patterning the first material layer, with the first layer serving as an etch stopper, thereby forming a second layer of the insulating layer, forming a second material layer on the second layer using the second material, and forming a resist mask on the second material layer and patterning the second material layer thereby thickening the second layer of the insulating layer, wherein the second layer in a second sub-pixel disposed in an area different from a reference area serving as a reference in a display region is thicker than the second layer in a first sub-pixel disposed in the reference area.

According to this manufacturing method, after forming the second layer of the insulating layer by patterning the first layer as an etch stopper, the step of thickening the second layer of the insulating layer is repeated multiple times so that the thickness of the second layer serving as an adjustment layer for the optical path length can be selectively made separately between the reference area and a display area different to the reference area. Thus, the thickness of the second layer in the second sub-pixel disposed in the peripheral area can be made thicker than the thickness of the second layer in the first sub-pixel disposed in the reference area.

Thus, it is possible to provide a method for manufacturing a light-emitting device capable of optimizing optical path length in both a reference area and at peripheral edge portions of a display region.

A method for manufacturing a light-emitting device including a reflective layer, an insulating layer, a light-emitting functional layer, and a semi-transmissive reflective layer, and moreover having a resonance structure in which light radiated from the light-emitting functional layer resonates between the reflective layer and the semi-transmissive reflective layer, the method including forming a first layer of the insulating layer, forming a material layer on the first layer using a second material, which is different from a first material, forming a resist on the material layer and performing gradient exposure using a gradient exposure mask, and patterning the material layer using a resist mask formed through the gradient exposure to transfer a shape of the resist mask onto the material layer, thereby forming a second layer of the insulating layer, wherein the second layer in a second sub-pixel disposed in an area different from a reference area serving as a reference in a display region is thicker than the second layer in a first sub-pixel disposed in the reference area.

According to this manufacturing method, patterning the material layer by using a resist mask formed by gradient exposure and transferring the shape of the resist mask to the material layer to form the second layer of the insulating layer makes it possible to selectively form the thickness of the second layer serving as the optical path length adjustment layer in the reference area and a display area different to the reference area. Thus, the thickness of the second layer in the second sub-pixel disposed in the peripheral area can be made thicker than the thickness of the second layer in the first sub-pixel disposed in the reference area.

Thus, it is possible to provide a method for manufacturing a light-emitting device capable of optimizing optical path length in both a reference area and peripheral edge portions of a display region.

What is claimed is:

1. A light-emitting device comprising:
a semi-transmissive reflection layer;
a first reflection layer that is disposed in a first sub-pixel;
a second reflection layer that is disposed in a second sub-pixel, the second sub-pixel that emits same color light as the first sub-pixel; and
a light-emitting functional layer that is disposed between the first reflection layer and the semi-transmissive reflection layer, and that is disposed between the second reflection layer and the semi-transmissive reflection layer, wherein
a distance between the second reflection layer and the semi-transmissive reflection layer is longer than a distance between the first reflection layer and the semi-transmissive reflection layer.

2. A light-emitting device comprising:
a semi-transmissive reflection layer;
a first reflection layer that is disposed in a first sub-pixel;
a first color filter that is disposed in the first sub-pixel, and that is disposed on an opposite-side of the semi-transmissive reflection layer from the first reflection layer;
a second reflection layer that is disposed in a second sub-pixel;
a second color filter that is disposed in the second sub-pixel, and that is disposed on an opposite-side of the semi-transmissive reflection layer from the second reflection layer, and that is same color as the first color filter; and
a light-emitting functional layer that is disposed between the first reflection layer and the semi-transmissive reflection layer, and that is disposed between the second reflection layer and the semi-transmissive reflection layer, wherein
a distance between the second reflection layer and the semi-transmissive reflection layer is longer than a distance between the first reflection layer and the semi-transmissive reflection layer.

3. The light-emitting device according to claim 1, further comprising:
a first pixel electrode that is disposed between the first reflection layer and the light-emitting functional layer;
a second pixel electrode that is disposed between the second reflection layer and the light-emitting functional layer; and
an insulating layer that is disposed between the first reflection layer and the first pixel electrode, and that is disposed between the second reflection layer and the second pixel electrode, the insulating layer having a first layer including a first material and a second layer including a second material which is different from the first material, wherein
a thickness of the second layer in the second sub-pixel is thicker than a thickness of the second layer in the first sub-pixel.

4. The light-emitting device according to claim 2, further comprising:
a first pixel electrode that is disposed between the first reflection layer and the light-emitting functional layer;
a second pixel electrode that is disposed between the second reflection layer and the light-emitting functional layer; and
an insulating layer that is disposed between the first reflection layer and the first pixel electrode, and that is disposed between the second reflection layer and the second pixel electrode, the insulating layer having a first layer including a first material and a second layer including a second material which is different from the first material, wherein
a thickness of the second layer in the second sub-pixel is thicker than a thickness of the second layer in the first sub-pixel.

5. The light-emitting device according to claim 1, wherein
the first sub-pixel is arranged in a center of a display region more than the second sub-pixel.

6. The light-emitting device according to claim 2, wherein
the first sub-pixel is arranged in a center of a display region more than the second sub-pixel.

7. The light-emitting device according to claim 3, wherein
the first sub-pixel is arranged in a center of a display region more than the second sub-pixel.

8. The light-emitting device according to claim 4, wherein
the first sub-pixel is arranged in a center of a display area more than the second sub-pixel.

9. An electronic apparatus comprising the light-emitting device of claim 1.
